(19) United States
(12) Patent Application Publication
(10) Pub. No.: US 2025/0301849 A1
(43) Pub. Date: Sep. 25, 2025

(54) DISPLAY DEVICE, LIGHT EMITTING ELEMENT, AND METHOD FOR MANUFACTURING THE SAME

(71) Applicant: Samsung Display Co., LTD., Yongin-si (KR)

(72) Inventor: Su Mi MOON, Yongin-si (KR)

(21) Appl. No.: 19/044,461

(22) Filed: Feb. 3, 2025

(30) Foreign Application Priority Data
Mar. 25, 2024 (KR) 10-2024-0040481

(51) Int. Cl. H10H 29/85; H01L 25/075; H10H 20/821; H10H 29/01; H10H 29/856

(52) U.S. Cl. CPC H10H 29/857; H01L 25/0753; H10H 20/821; H10H 29/0364; H10H 29/856

(57) ABSTRACT

A display device, a light emitting element, and a manufacturing method of the display device are provided. The display device includes: a substrate on which a pixel electrode is located; a light emitting element on the pixel electrode and including an element rod and a contact electrode on one surface and a side surface of the element rod; a connection electrode electrically connecting the contact electrode and the pixel electrode; and a common electrode on the light emitting element, wherein the element rod includes: a first element rod including a first semiconductor layer and an active layer and having a side surface having a first inclination angle; a second element rod on the first element rod and having a side surface having a second inclination angle; and a third element rod on the second element rod and having a side surface having a third inclination angle.

### CROSS-REFERENCE TO RELATED APPLICATION

This application claims priority to and the benefit of Korean Patent Application No. 10-2024-0040481, filed on Mar. 25, 2024, in the Korean Intellectual Property Office, the entire disclosure of which is incorporated by reference herein.

### BACKGROUND

### 1. Field

The present disclosure relates to a display device, a light emitting element, and a manufacturing method of the display device.

### 2. Description of the Related Art

As the information society develops, demands for display devices for displaying images are increasing in various forms. The display devices may be flat panel display devices such as liquid crystal displays, field emission displays, and light emitting displays.

The light emitting displays include an organic light emitting display including an organic light emitting diode element as a light emitting element and a micro-light emitting display including a micro-light emitting diode element (hereinafter, referred to as a micro-light emitting element) as a light emitting element. Since micro-light emitting diode elements are made of inorganic materials, they have less deterioration issues and thus a longer life than organic light emitting diode elements.

### SUMMARY

Aspects and features of embodiments of the present disclosure are to provide a display device, a light emitting element, and a manufacturing method of the display device that may prevent short circuits between a common electrode and a contact electrode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device. The display device includes a substrate on which a pixel electrode is located; a light emitting element on the pixel electrode and including an element rod and a contact electrode on one surface and a side surface of the element rod, a connection electrode electrically connecting the contact electrode and the pixel electrode; and a common electrode on the light emitting element, wherein the element rod includes: a first element rod including a first semiconductor layer and an active layer and having a side surface having a first inclination angle; a second element rod on the first element rod and having a side surface having a second inclination angle; and a third element rod on the second element rod and having a side surface having a third inclination angle, wherein the light emitting element further includes: a first protective layer on one side and a side of the first element rod and on a side of the second element rod, a reflective layer on the first protective layer and on one side and a side of the first element rod and on a side of the second element rod; and a second protective layer on the side surface of the second element rod, the side surface of the third element rod, and an edge of a top surface of the third element rod.

The contact electrode is on one surface of the first element rod on the reflective layer and extends to the side surface of the first element rod and the side surface of the second element rod.

The contact electrode is located between the reflective layer and the second protective layer on the side of the second element rod, wherein one end of the reflective layer is surrounded by the first protective layer and the contact electrode on the side of the second element rod.

The first protective layer, the reflective layer, and the contact electrode are not on the side of the third element rod.

A third semiconductor layer of the element rod has a concavo-convex structure.

The second protective layer extends from the side of the third element rod and is located at an edge of the concavo-convex structure of the third semiconductor layer.

The second protective layer becomes thinner from a top surface of a third semiconductor layer of the element rod inwardly.

The display device further includes an organic pattern layer on the pixel electrode and on a lower surface of the light emitting element, wherein the connection electrode is on one side of the pixel electrode, a side of the organic pattern layer, and a side of a first contact electrode of the contact electrode of the light emitting element.

The first protective layer has one or more openings defined on one surface of the first element rod, wherein the contact electrode is electrically connected to the element rod exposed by the opening.

The contact electrode has higher conductivity and lower reflectivity than the reflective layer.

The second inclination angle is smaller than the first inclination angle and the third inclination angle.

The second inclination angle is between 60 degrees and 80 degrees.

A width of the second element rod becomes wider toward the third element rod, and a width of the third element rod is wider than a width of the first element rod.

A light emitting element includes an element rod in which a first semiconductor layer, an active layer, a second semiconductor layer, and a third semiconductor layer are stacked in sequence, and are compartmentalized into a first element rod, a second element rod, and a third element rod according to an inclination angle, a first protective layer on one side and a side of the first element rod and on a side of the second element rod, a reflective layer on the first protective layer and on the one side and the side of the first element rod and on the side of the second element rod, a contact electrode on the one side of the first element rod on the reflective layer and extending to the side of the first element rod and the side of the second element rod, and a second protective layer on the side of the second element rod, a side of the third element rod, and an edge of a top surface of the third element rod.

The third semiconductor layer has a concavo-convex structure, wherein the second protective layer is at an edge of the concavo-convex structure of the third semiconductor layer.

The second protective layer becomes thinner from a top surface of the third semiconductor layer inwardly.

A second inclination angle of the second element rod is smaller than a first inclination angle of the first element rod and a third inclination angle of the third element rod, wherein the second inclination angle is between 60 degrees and 80 degrees.

According to one or more embodiments of the present disclosure, there is provided manufacturing method of a display device. A manufacturing method of a display device includes forming a third semiconductor material layer, a second semiconductor material layer, an active material layer, and a first semiconductor material layer on a growth substrate, forming a first element rod having a first inclination angle by etching the active material layer and the first semiconductor material layer using a first mask, forming a second element rod having a second inclination angle by etching the second semiconductor material layer and the third semiconductor material layer using a second mask, forming a first protective layer, a reflective layer, and a contact electrode covering the third semiconductor material layer, the second semiconductor material layer, the active material layer, and the first semiconductor material layer, forming a third element rod having a third inclination angle by etching a portion of the second element rod using a third mask, and forming a second protective layer on a side surface of the second element rod and a side surface of the third element rod, wherein the second protective layer extends from the side surface of the third element rod and is between an edge gap between the third element rod and the second protective layer.

The method further includes transferring a light emitting element including the first element rod, the second element rod, and the third element rod to a circuit board having a pixel electrode, and forming a connection electrode connecting the contact electrode and the pixel electrode.

The transferring the light emitting element to the circuit board having the pixel electrode includes: forming an organic pattern layer as a pseudo adhesive layer on the pixel electrode, and arranging a plurality of light emitting elements on the organic pattern layer and fixing the light emitting elements by curing the organic pattern layer.

In the display device and its manufacturing method according to one or more embodiments, short circuits between the common electrode and the contact electrode of light emitting elements may be reduced or minimized.

However, the effects, aspects, and features, of the present disclosure are not limited to the aforementioned effects, aspects, and features, and various other effects, aspects, and features are included in the present disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments;

FIG. 2 is a layout view of a display device according to one or more embodiments;

FIG. 3 is a block diagram of a display device according to one or more embodiments;

FIG. 4 is an equivalent circuit diagram of a subpixel according to one or more embodiments;

FIG. 5 is a layout diagram illustrating pixels of a display area according to one or more embodiments;

FIG. 6 is a cross-sectional view illustrating of a cross-section of a display panel corresponding to the line I1-I1′ of FIG. 5 according to one or more embodiments;

FIG. 7 is a detailed cross-sectional view illustrating an example of an area A of FIG. 6 according to one or more embodiments;

FIG. 8 is a detailed cross-sectional view illustrating an example of the area A of FIG. 6 according to one or more embodiments;

FIG. 9 is a detailed cross-sectional view illustrating an example of the area A of FIG. 6 according to one or more embodiments;

FIG. 10 is a layout diagram illustrating pixels of a display area according to one or more embodiments;

FIG. 11 is a cross-sectional view illustrating an example of cross-section of a display panel corresponding to the line I2-I2′ in FIG. 10;

FIG. 12 is a cross-sectional view illustrating an example of an area B in FIG. 11 in detail;

FIG. 13 is a flowchart illustrating a manufacturing method of a display device according to one or more embodiments;

FIGS. 14-22 are cross-sectional views to illustrate a manufacturing method of a display device according to one or more embodiments;

FIG. 23 is a view illustrating an example of an area C in FIG. 22 in detail;

FIGS. 24-29 are cross-sectional views to further illustrate the manufacturing method of a display device according to one or more embodiments;

FIG. 30 is an example view of a smart watch including a display device according to one or more embodiments;

FIGS. 31 and 32 are example views of a virtual reality (VR) device including a display device according to one or more embodiments;

FIG. 33 is an example view of a VR device including a display device according to one or more embodiments;

FIG. 34 is an example view illustrating a vehicle instrument cluster and

center fascia including display devices according to one or more embodiments; and

FIG. 35 is an example view of a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display device, a light emitting element, and a manufacturing method of the display device will be described with reference to the accompanying drawings.

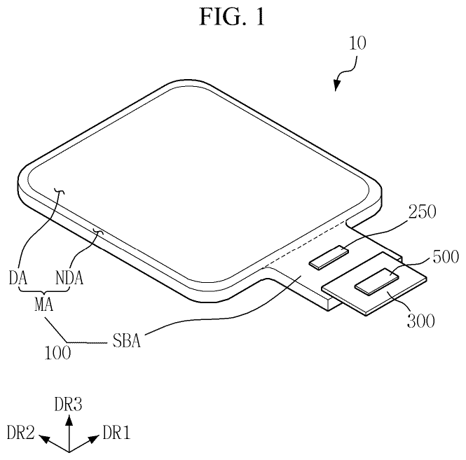

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display such as an organic light emitting display using an organic light emitting diode (OLED), a quantum dot light emitting display including a quantum dot light emitting layer, an inorganic light emitting display including an inorganic semiconductor, or a micro- or nano-light emitting display using a micro- or nano-light emitting diode (LED). A case where the display device 10 is a micro- or nano-light emitting display will be mainly described below, but the present disclosure is not limited thereto. For ease of description, a micro- or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

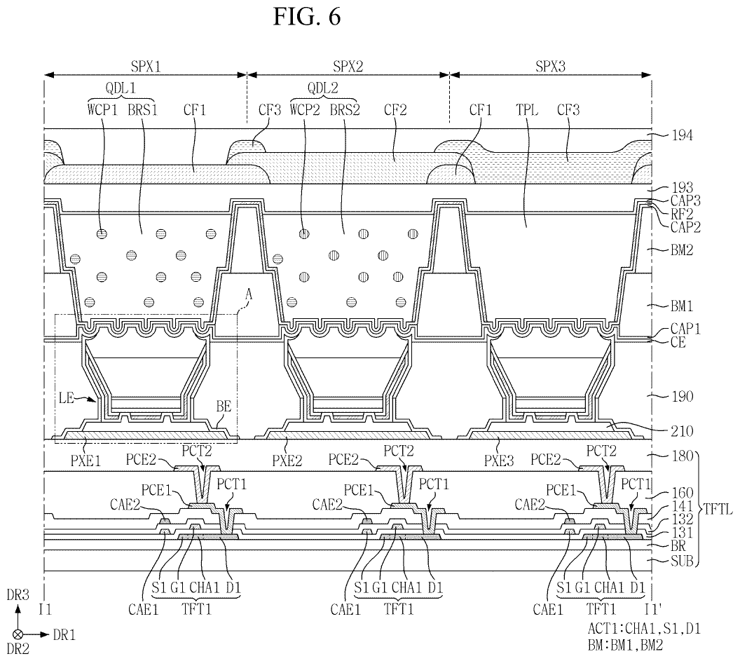

A substrate SUB (e.g., see FIG. 6) of the display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels that displays an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In such a case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

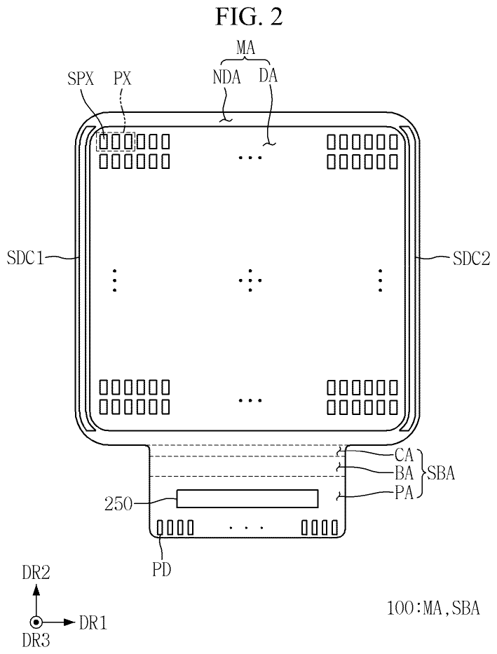

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

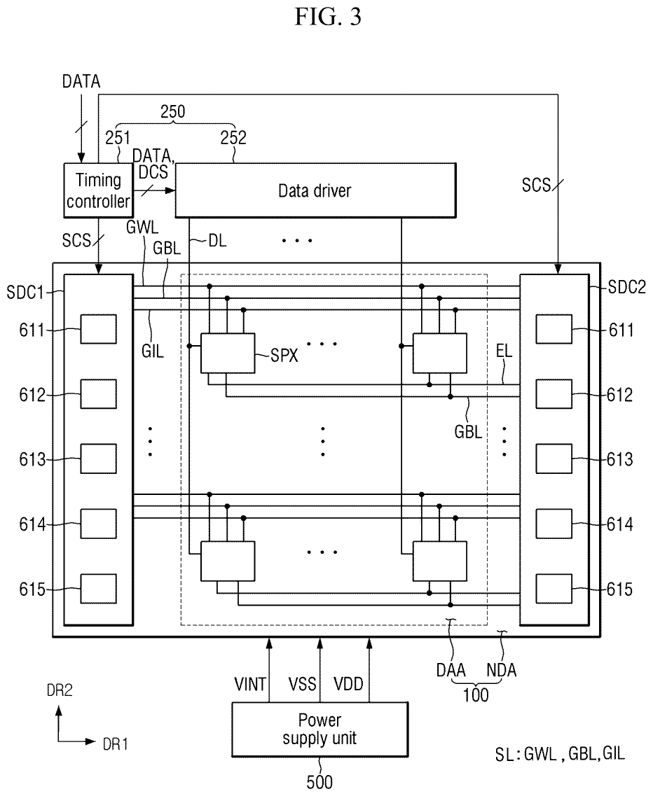

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form in the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the initialization scan lines GIL, one of the bias scan lines GBL, one of the emission control lines EL, and one of the data lines DL. In some embodiments, each of the subpixels SPX may be connected to one of the control scan lines. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, a control scan signal output unit 612, an initialization scan signal output unit 613, a bias scan signal output unit 614. Each of the write scan signal output unit 611, the control scan signal output unit 612, the initialization scan signal output unit 613, the bias scan signal output unit 614, and the emission signal output unit 615 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The control scan signal output unit 612 may generate control scan signals according to the scan timing control signal SCS and sequentially output the control scan signals to the control scan lines. The initialization scan signal output unit 613 may generate initialization scan signals according to the scan timing control signal SCS and sequentially output the initialization scan signals to the initialization scan lines GIL. The bias scan signal output unit 614 may generate bias scan signals according to the scan timing control signal SCS and sequentially output the bias scan signals to the bias scan lines GBL. The emission signal output unit 615 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first driving voltage VDD, a second driving voltage VSS, and a third driving voltage VINT and supply them to the display panel 100.

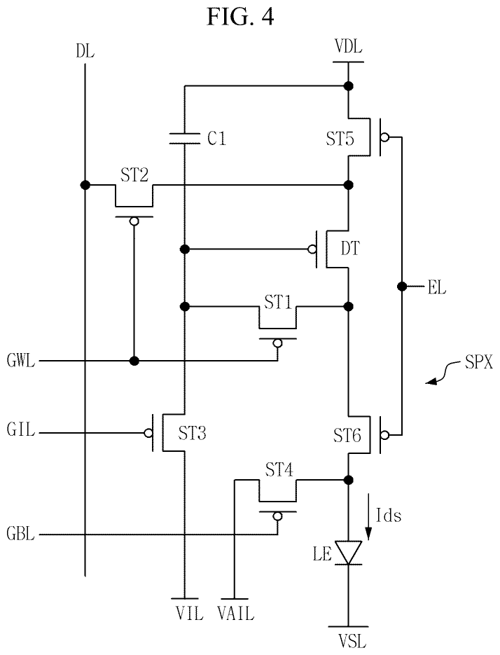

FIG. 4 is an equivalent circuit diagram of a subpixel SPX according to one or more embodiments.

Referring to FIG. 4, the subpixel SPX according to the embodiment may be connected to scan lines GWL, GIL, and GBL, an emission control line EL, and a data line DL. For example, the subpixel SPX may be connected to a write scan line GWL, an initialization scan line GIL, a bias scan line GBL, the emission line EL, and the data line DL.

The subpixel SPX according to the embodiment includes a driving transistor DT, switch elements, a capacitor C1, and a light emitting element LE1. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light emitting element LE1 may be a micro-LED.

The light emitting element LE1 emits light according to the driving current Ids. The amount of light emitted from the light emitting element LE1 may be proportional to the driving current Ids. An anode of the light emitting element LE1 may be connected to a first electrode of the fourth transistor ST4 and a second electrode of the sixth transistor ST6, and a cathode may be connected to a second power line VSL to which a second power supply voltage (e.g., VSS) is applied.

The capacitor C1 is formed between the gate electrode of the driving transistor DT and a first power line VDL to which a first power supply voltage (e.g., VDD) is applied. The first power supply voltage may be at a higher level than the second power supply voltage. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors ST5 and ST6 may be connected to the emission line EL. Because the first through sixth transistors ST1 through ST6 are formed as p-type MOSFETs, they may be turned on when a scan signal of a gate-low voltage and an emission control signal of a gate-low voltage are transmitted to the initialization scan line GIL, the write scan line GWL, the bias scan line GBL, and the emission line EL. One electrode of the third transistor ST3 and one electrode of the fourth transistor ST4 may be connected to an initialization voltage line VIL or VAIL.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

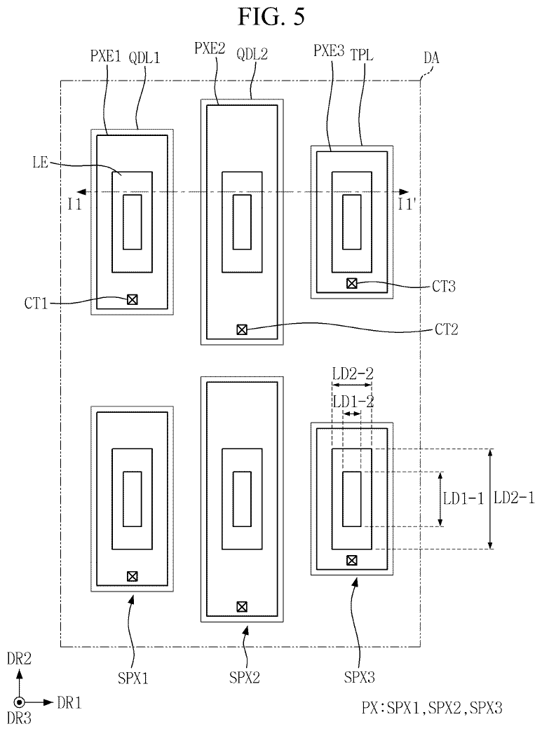

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. Each of the plurality of pixels PX includes three sub-pixels SPX1, SPX2, and SPX3, which include the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer TPL.

Each of the first pixel electrode PXE1, the second pixel electrode PXE2, and the third pixel electrode PXE3 may have a rectangular planar shape with a short side in the first direction DR1 and a long side in the second direction DR2.

The light emitting element LE may have a rectangular planar shape with a short side in the first direction DR1 and a long side in the second direction DR2.

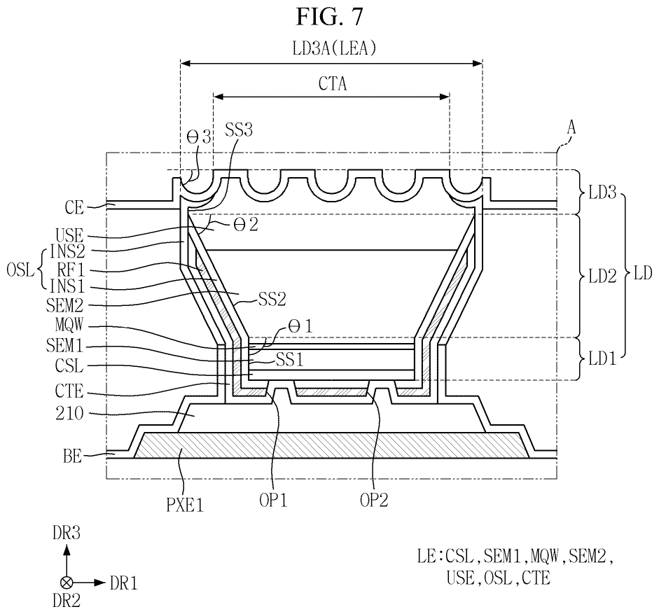

As will be described later, the light emitting element LE may include an element rod compartmentalized into a first element rod (LD1 in FIG. 7), a second element rod (LD2 in FIG. 7), and a third element rod (LD3 in FIG. 7). The first element rod LD1, the second element rod LD2, and the third element rod LD3 each follow the planar shape of the light emitting element LE. For example, the first element rod LD1, the second element rod LD2, and the third element rod may have a rectangular planar shape having a short side in the first direction DR1 and a long side in the second direction DR2.

The length of the short side LD2-2 of the element rod LD is approximately 13 μm to 11 μm, and the length of the long side LD2-1 is 20 μm to 22 μm and may be 23 μm to 26 μm. In addition, the length of the short side LD1-1 of the first element rod LD may be about 6 μm to 7 μm, and the length of the long side LD1-2 may be 20 μm to 22 μm, but this is only an example and not limited to this.

Depending on the light conversion efficiency of the first light conversion layer QDL1 and the light conversion efficiency of the second light conversion layer QDL2, the area of the first sub-pixel SPX1, the area of the second sub-pixel SPX2, and the area of the third sub-pixel SPX3 may be set. That is, the lower the light conversion efficiency, the larger the area of the sub-pixel may be.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the first pixel electrode PXE1 may be larger than the area of the third pixel electrode PXE3.

Each of the pixel electrodes PXE1, PXE2, and PXE3 may be electrically connected to at least one transistor through the pixel connection hole (CT1/CT2/CT3). For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

A plurality of light emitting elements LE may be disposed on each of the pixel electrodes PXE1, PXE2, and PXE3. The same number of light emitting elements LE may be disposed on each of the pixel electrodes PXE1, PXE2, and PXE3. For example, one light emitting element LE may be disposed on each of the pixel electrodes PXE1, PXE2, and PXE3. The plurality of light emitting elements LE may emit light of a third color, that is, light in a blue wavelength band, but the present disclosure is not limited thereto. When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into the first light.

The second light conversion layer QDL2 may completely overlap the plurality of light emitting elements LE and the second pixel electrode PXE2 of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into the second light.

The light transmission layer TPL may completely overlap the plurality of light emitting elements LE and the third pixel electrode PXE3 of the third sub-pixel SPX3. The light transmission layer TPL may transmit incident light as it is. For example, the light transmission layer TPL may directly transmit the third light emitted from the plurality of light emitting elements LE of the third sub-pixel SPX3.

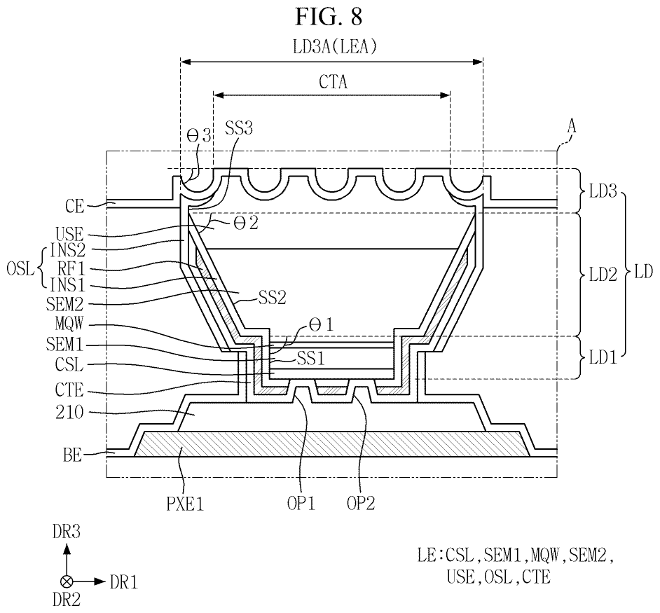

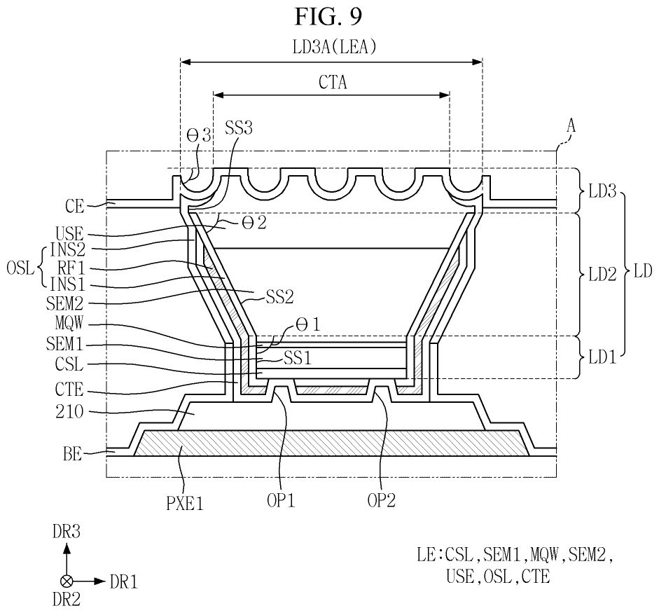

FIG. 6 is a cross-sectional view illustrating of a cross-section of a display panel corresponding to the line I1-I1′ of FIG. 5 according to one or more embodiments. FIG. 7 is a detailed cross-sectional view illustrating an example of an area A of FIG. 6 according to one or more embodiments. FIGS. 8 and 9 are detailed cross-sectional views illustrating an example of the area A of FIG. 6 according to one or more other embodiments.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminum oxide layer.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and the barrier film BR.

A first gate metal layer may be disposed on the first gate insulating film 131. The first gate metal layer may include the first gate electrode G1 of the thin film transistor TFT1 and the first capacitor electrode CAE1. The first gate electrode G1 may overlap the first active layer ACT1 in the third direction DR3. In FIG. 6, the first gate electrode G1 and the first capacitor electrode CAE1 are illustrated to be spaced (e.g., disposed apart) from each other, but the first gate electrode G1 and the first capacitor electrode CAE1 may be connected to each other.

A second gate insulating film 132 may be disposed on the first gate electrode G1 of the thin film transistor TFT1, the first capacitor electrode CAE1, and the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first organic film 160 may be disposed on the first source connection electrode PCE1 and the first interlayer insulating film 141 to flatten the step caused by the thin film transistor TFT1.

A second data metal layer may be disposed on the first organic film 160. The second data metal layer may include a second source connection electrode PCE2. The second source connection electrode PCE2 may be connected to the first source connection electrode PCE1 through a second pixel contact hole PCT2 penetrating the first organic film 160.

A second organic film 180 may be disposed on the second source connection electrode PCE2 and the first organic film 160.

The barrier film BR, the first gate insulating film 131, the second gate insulating film 132, and the first interlayer insulating film 141 may be formed of an inorganic film, such as a silicon nitride layer, a silicon oxynitride layer, a silicon oxide layer, a titanium oxide layer, and/or an aluminum oxide layer.

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first organic film 160 and the second organic film 180 may be formed of an organic film such as an acrylic resin, an epoxy resin, a phenolic resin, a polyamide resin, a polyimide resin, and/or the like.

A light emitting element layer may be disposed on the second organic film 180. The light emitting element layer may include pixel electrodes PXE1, PXE2, and PXE3, common electrode CE, light emitting elements LE, and an organic layer 190.

A pixel electrode layer may be disposed on the second organic film 180.

The pixel electrode layer may include pixel electrodes PXE1, PXE2, and PXE3. The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

An organic layer 210 (hereinafter referred to as an organic pattern layer to distinguish it from the organic films 180 and 190 disposed on the entire surface of the lower structure) may be disposed on each of the pixel electrodes PXE1, PXE2, and PXE3. An organic pattern layer 210 temporarily fix and/or adhere the plurality of light emitting elements LE to prevent them from tilting or falling over in the process of transferring the plurality of light emitting elements LE to the display panel. That is, the organic pattern layer 210 may be a film for temporarily adhering the plurality of light emitting elements LE onto each of the pixel electrodes PXE1, PXE2, and PXE3. To facilitate temporary adhesion, the thickness of the organic pattern layer 210 may be greater than the thickness of each of the pixel electrodes PXE1, PXE2, and PXE3.

The organic pattern layer 210 may be a photosensitive organic film such as a photoresist. Alternatively, the organic pattern layer 210 may be formed from an acrylic resin, an epoxy resin, a phenolic resin, a polyamide resin, a polyimide resin, and/or the like.

The organic pattern layer 210 may be disposed on the bottom surface of a contact electrode CTE.

The plurality of light emitting elements LE may be disposed on the organic pattern layer 210. FIG. 6 illustrates that each of the plurality of light emitting elements LE is a vertical type micro LED extending in the third direction DR3. The vertical micro LED refers to an LED having a structure in which a first semiconductor layer SEM1, an active layer MQW, a second semiconductor layer SEM2, and a third semiconductor layer USE are arranged sequentially along the third direction DR3, which is a vertical direction.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3 of several to hundreds of μm, respectively. For example, each of the plurality of light emitting elements LE may have a length in the first direction DR1, a length in the second direction DR2, and a length in the third direction DR3 of approximately 100 μm or less.

Each of the light emitting elements LE may include a current spreading layer CSL, a first semiconductor layer SEM1, an active layer MQW, a second semiconductor layer SEM2, a third semiconductor layer USE, an outer shell layer OSL, and a contact electrode CTE. In one or more embodiments, each of the light emitting elements LE may omit the current spreading layer CSL.

The current spreading layer CSL is disposed on the contact electrode CTE and is a layer to increase light extraction efficiency. The current spreading layer CSL may be formed of a transparent conductive oxide (TCO) such as indium tin oxide (ITO) and/or indium zinc oxide (IZO) to allow light to pass through.

The first semiconductor layer SEM1 may be disposed on the current spreading layer CSL (on the contact electrode CTE if the current spreading layer CSL is omitted), the active layer MQW may be disposed on the first semiconductor layer SEM1, the second semiconductor layer SEM2 may be disposed on the active layer MQW, and the third semiconductor layer USE may be disposed on the second semiconductor layer SEM2.

The first semiconductor layer SEM1 may be made of GaN doped with a first conductivity type dopant (e.g., p-type dopant) such as Mg, Zn, Ca, Sr, Ba, and/or the like.

The first semiconductor layer SEM1 may be electrically connected to the pixel electrode PXE of each sub-pixel SPX. For example, the first semiconductor layer SEM1 may be electrically connected to the pixel electrode PXE of each sub-pixel SPX through the current spreading layer CSL and the contact electrode CTE.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt % to 20 wt %.

The second semiconductor layer SEM2 may be disposed on the active layer MQW. The second semiconductor layer SEM2 may be doped with a second conductivity type dopant such as Si, Ge, Sn, and/or the like. For example, the second semiconductor layer SEM2 may be n-GaN doped with n-type Si.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or p-AlGaN doped with p-type Mg. The electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The third semiconductor layer USE may have a concave-convex structure on its top surface. For example, the third semiconductor layer USE may be an undoped semiconductor grown on a patterned sapphire substrate (PSS). The third semiconductor layer USE may be a material that is not doped as n-type or p-type. In one or more embodiments, the third semiconductor layer USE may be undoped InAlGaN, GaN, AlGaN, InGaN, AlN, and/or InN but is not limited thereto.

The current spreading layer CSL, the first semiconductor layer SEM1, the active layer MQW, the second semiconductor layer SEM2, and the third semiconductor layer USE of the light emitting element LE may be referred to as the element rod LD.

The element rod LD may include a first element rod LD1, a second element rod LD2, and a third element rod LE3, which are classified according to a change in the inclination angle of the side.

The first element rod LD1 may include a first sidewall SS1 having a first inclination angle θ1. The first inclination angle θ1 of the first sidewall SS1 may be formed at 90 degrees as shown in FIGS. 7-9 but is not limited thereto. For example, the first inclination angle θ1 may be 70 degrees or more and less than 90 degrees. The first inclination angle θ1 is an angle between the second semiconductor layer SEM2 and an extension of the contact surface of the first element rod LD1 and the second element rod LD2 and a first sidewall SS1 of the first element rod LD1.

The height of the first element rod LD1 may be the lowest from among the three element rods LD1, LD2, and LD3. That is, the height of the first element rod LD1 is lower than the height of the second element rod LD2 and the height of the third element rod LD3.

The first element rod LD1 may include the first semiconductor layer SEM1 and the active layer MQW.

The second element rod LD2 is disposed on the first element rod LD1.

The height of the second element rod LD2 may be the highest from among the element rods LD1, LD2, and LD3.

The second element rod LD2 may include a second sidewall SS2 having a second inclination angle θ2. The second inclination angle θ2 of the second sidewall SS2 may be 60 degrees or more and 80 degrees or less. Additionally, the second inclination angle θ2 may be smaller than the first inclination angle θ1. Therefore, the second sidewall SS2 may be formed as a regular taper. The width of the second element rod LD2 becomes wider toward the top, that is, toward the third element rod LE3. The second inclination angle θ2 is an angle between an extension of the contact surface of the second element rod LD2 and the third element rod LD3 and the second sidewall SS2 of the second element rod LD2.

As shown in FIG. 8, the areas of the surfaces of the first element rod LD1 and the second element rod LD2 facing each other may match each other but is not limited to this.

As shown in FIG. 9, the areas of the surfaces of the first element rod LD1 and the second element rod LD2 facing each other may mismatched each other, so that the first element rod LD1 and the second element rod LD2 may be formed to have a step.

The second element rod LD2 may include the second semiconductor layer SEM2.

The third element rod LD3 may be disposed on the second element rod LD2. The third element rod LD3 may include a third sidewall SS3 having a third inclination angle θ3. The third inclination angle θ3 of the third sidewall SS3 may be formed at 90 degrees as shown in FIG. 7 but is not limited thereto. For example, the third inclination angle θ3 may be 70 degrees or more and less than 90 degrees.

The third element rod LD3 may include a portion of the third semiconductor layer USE. In one or more other embodiments, the third element rod LD3 may include a portion of the second semiconductor layer SEM2 and the third semiconductor layer USE.

When the total height of the element rod LD is 6 μm, the height of the first element rod LD1 may be in the range of 0.5 μm to 1.2 μm, the height of the second element rod LD2 may be in the range of 2.3 μm to 2.7 μm, and the height of the third element rod LD3 may be in the range of 1.5 μm to 2.3 μm, but this is for illustrative purposes only and is not limited thereto.

Each of the plurality of light emitting elements LE may be formed by growing on a semiconductor substrate such as a silicon substrate and/or sapphire substrate. The plurality of light emitting elements LE may be directly transferred from the semiconductor substrate onto the pixel electrodes PXE1, PXE2, and PXE3 of the display panel 100. Alternatively, the plurality of light emitting elements LE may be transferred onto the pixel electrodes PXE1, PXE2, and PXE3 of the display panel 100 through an electrostatic method using an electrostatic head and/or a stamp method using an elastic polymer material such as PDMS and/or silicon as a transfer substrate.

The outer shell layer OSL may be disposed on at least a side of the first element rod LD1, a side of the second element rod LD2, and a side of the third element rod LD3. For example, the outer shell layer OSL is on at least one side of the current spreading layer CSL, the first semiconductor layer SEM1, the second semiconductor layer SEM2, the active layer MQW, and the third semiconductor layer USE. The outer shell layer OSL may include a first protective layer INS1, a first reflective layer RF1, and a second protective layer INS2.

The first protective layer INS1 and the second protective layer INS2 may comprise materials having insulating properties, for example, inorganic insulating materials such as silicon oxide (SiOx), silicon nitride (SiNx), silicon oxynitride (SiOxNy), aluminum oxide (AlxOy), aluminum nitride (AlN), and/or the like.

The first protective layer INS1 may be disposed on at least one side of the current spreading layer CSL, the first semiconductor layer SEM1, the second semiconductor layer SEM2, the active layer MQW, and the third semiconductor layer USE.

The first protective layer INS1 may include one or more openings on one side of the current spreading layer CSL. For example, the first protective layer INS1 may include a first opening OP1 and a second opening OP2 that are spaced (e.g., spaced apart) from each other.

At least a portion of the current spreading layer CSL may be exposed through the first opening OP1 and the second opening OP2.

In one or more embodiments, the first protective layer INS1 may be made of a single layer or a multilayer of materials with insulating properties. The first protective layer INS1 can prevent an electrical short circuit that may occur when the active layer MQW directly contacts an electrode through which an electrical signal is transmitted to the element rod LD. Furthermore, because the first protective layer INS1 covers the outer peripheral surface of the active layer MQW and protects the outer surface (e.g., the outer peripheral surface) of the element rod LD, a decrease in luminous efficiency may be reduced or prevented.

The first reflective layer RF1 may be disposed on the first protective layer INS1 to be around (e.g., to surround) at least one side of the element rod LD, for example, the side surfaces of the first element rod LD1 and the second element rod LD2. The first reflective layer RF1 may not be disposed on the side of the third element rod LD3.

The first reflective layer RF1 may include a metallic material that is conductive and highly reflective of light (e.g., greater than 90% reflectivity). The first reflective layer RF1 may include, for example, aluminum (Al), chromium (Cr), and/or silver (Ag), and/or an alloy thereof, and may comprise a single layer or multiple layers thereof. The multilayer may be, for example, two layers of titanium/aluminum, two layers of nickel/aluminum, two layers of a silver/aluminum-silicon alloy, etc. The first reflective layer RF1 allows light emitted from the light emitting element LE to exit upward.

The first reflective layer RF1 may use omni-directional reflectors (ODR) but is not limited thereto. An omnidirectional reflector refers to a reflector that maintains high reflectivity over a wide wavelength range and a wide angle of incidence. The first reflective layer RF1 may have a reflectivity of 90% or more in the visible range.

The contact electrode CTE may be disposed on the first reflective layer RF1, on the entire bottom and side of the first element rod LD1, and on the side of the second element rod LD2. The contact electrode CTE may be formed to cover one end of the first reflective layer RF1 disposed on the side of the second element rod LD2.

One end of the contact electrode CTE may be arranged in a straight line in alignment with the third element rod LD3 and the side surface of the third element rod LD3, but the present disclosure is not limited to this. For example, as shown in FIG. 9, the third element rod LD3 and the side surface of the third element rod LD3 may be disposed further outside of one end of the contact electrode CTE. When the third element rod LD3 and the side surface of the third element rod LD3 are disposed further outside of one end of the contact electrode CTE, the height of the third element rod LD3 may be lowered.

The contact electrode CTE may contact the current spreading layer CSL exposed by the first opening OP1 and the second opening OP1. When the current spreading layer CSL is omitted, the contact electrode CTE may contact the first semiconductor layer SEM1.

Because the contact electrode CTE is disposed on the outermost side of one surface of the first element rod LD1, it may be disposed on the organic pattern layer 210. The contact electrode CTE may include molybdenum (Mo), aluminum (Al), chromium (Cr), gold (Au), titanium (Ti), nickel (Ni), neodymium (Nd), and/or copper (Cu).

The second protective layer INS2 may be disposed on at least a portion of the side of the element rod LD. For example, the second protective layer INS2 may be disposed on the side of the second element rod LD2 and the third element rod LD3, and may extend from the side of the third element rod LD3 and may be disposed at least partially on the top surface of the third element rod LD3. For example, the second protective layer INS2 may be disposed at the edge of the top surface of the third element rod LD3. The second protective layer INS2 may be disposed along irregularities on the top surface of the third element rod LD3. The second protective layer INS2 may be disposed to become thinner from the outer side of the top surface of the third element rod LD3 to the inner side.

Accordingly, the contact area CTA between the common electrode CE and the third element rod LD3 on a plane may be smaller than the area LD3A of the third element rod LD3. Additionally, on a plane (e.g., in a plan view), the area of the third element rod LD3 may be the same as the area of the light emitting element LE, so the contact area CTA between the common electrode CE and the third element rod LD3 may be the same as the area of the third element rod LD3.

The second protective layer INS2 may cover and protect at least one end of the contact electrode CTE.

A connection electrode BE connects the contact electrode CTE of the light emitting element LE with one of the pixel electrodes PXE1, PXE2, and PXE3. The connection electrode BE may be connected to any one of the exposed pixel electrodes PXE1, PXE2, and PXE3 through a connection hole penetrating the organic pattern layer 210. Further, the connection electrode BE may be disposed on the top surface of the organic pattern layer 210 and the side surface of the contact electrode CTE. Additionally, the connection electrode BE may be disposed on a portion of the side surface of the light emitting element LE. For example, the connection electrode BE may be disposed on the contact electrode CTE on the side of the first element rod LD1.

The connection electrode BE may include molybdenum (Mo), aluminum (Al), chromium (Cr), gold (Au), titanium (Ti), nickel (Ni), neodymium (Nd), and copper (Cu). Alternatively, the connection electrode BE may be made of a transparent conductive material (TCO), such as indium tin oxide (ITO) and/or indium zinc oxide (IZO), which can transmit light.

The third organic layer 190 may be disposed to cover a portion of the side surfaces of the plurality of light emitting elements LE. Further, the third organic layer 190 may be disposed to cover the connection electrode BE.

The top surface of each of the plurality of light emitting elements LE may be exposed without being covered by the third organic layer 190.

The third organic layer 190 may be formed of an organic film, such as an acrylic resin, an epoxy resin, a phenolic resin, a polyamide resin, a polyimide resin, and/or the like.

The common electrode CE may be disposed on the top surface of each of the plurality of light emitting elements LE and the top surface of the third organic layer 190. The common electrode CE may be a common layer commonly formed in the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

In one or more embodiments, the pixel electrodes PXE1, PXE2, and PXE3 may be referred to as an anode electrode or a first electrode, and the common electrode CE may be referred to as a cathode electrode or a second electrode.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by dividing the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE.

The first light conversion layer QDL1 may convert a portion of the third light (light in the blue wavelength band) incident from the light emitting element LE into first light (light in the red wavelength band). The first light conversion layer QDL1 may include a first base resin BRS1 and first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, and/or an imide-based resin. The first and second wavelength conversion particles WCP1 and WCP2 may be quantum dots QD, quantum rods, fluorescent materials, and/or phosphorescent materials.

The light blocking layer BM may include a first light blocking layer BM1 and a second light blocking layer BM2 that are sequentially stacked. A length in the first direction DR1 or a length in the second direction DR2 of the first light blocking layer BM1 may be wider than a length in the first direction DR1 or a length in the second direction DR2 of the second light blocking layer BM2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from traveling to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The second reflective layer RF2 may be disposed between the light blocking layer BM and the first light conversion layer QDL1, between the light blocking layer BM and the second light conversion layer QDL2, and between the light blocking layer BM and the light transmission layer TPL. The second reflective layer RF2 may be disposed on the second capping layer CAP2 disposed on a side of the first light blocking layer BM1 and on a side of the second light blocking layer BM2. The second reflective layer RF2 serves to reflect light traveling in the lateral direction from the first light conversion layer QDL1, the second light conversion layer QDL2, and the light transmission layer TPL.

The second reflective layer RF2 may include a highly reflective metal material such as aluminum (Al). The thickness of the second reflective layer RF2 may be approximately 0.1 μm.

Alternatively, the second reflective layer RF2 may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, a silicon nitride layer, a silicon oxynitride layer, a silicon oxide layer, a titanium oxide layer, and/or an aluminum oxide layer.

The third capping layer CAP3 may be disposed on the second capping layer CAP2, the second reflective layer RF2, the first light conversion layer QDL1, the second light conversion layer QDL2, and the light transmission layer TPL.

The first capping layer CAP1, the second capping layer CAP2, and the third capping layer CAP3 may be formed from an inorganic film, such as a silicon nitride layer, a silicon oxynitride layer, a silicon oxide layer, a titanium oxide layer, and/or an aluminum oxide layer. The first light conversion layer QDL1, the second light conversion layer QDL2, and the light transmission layer TPL may be encapsulated by the first capping layer CAP1, the second capping layer CAP2, and the third capping layer CAP3.

A fourth organic film 193 may be disposed on the third capping layer CAP3. A plurality of color filters CF1, CF2, and CF3 may be disposed on the fourth organic film 193. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band) and absorb or block the third light (light in the blue wavelength band). Therefore, the first color filter CF1 may transmit the first light (light in the red wavelength band) that has been converted by the first light conversion layer QDL1 from among the third light (light in the blue wavelength band) emitted from the light emitting element LE and absorb or block the third light (light in the blue wavelength band) that has not been converted by the first light conversion layer QDL1. Accordingly, the first sub-pixel SPX1 may emit the first light (light in the red wavelength band).

The second color filter CF2 disposed in the second sub-pixel SPX2 may transmit the second light (light in the green wavelength band) and absorb or block the third light (light in the blue wavelength band). Therefore, the second color filter CF2 may transmit the second light (light in the green wavelength band) that has been converted by the second light conversion layer QDL2 from among the third light (light in the blue wavelength band) emitted from the light emitting element LE and absorb or block the third light (light in the blue wavelength band) that has not been converted by the second light conversion layer QDL2. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the light blocking layer BM in the third direction DR3.

A fifth organic film 194 may be disposed on the plurality of color filters CF1, CF2, and CF3 for planarization.

The fourth organic film 193 and the fifth organic film 194 may be formed from an acrylic resin, an epoxy resin, a phenolic resin, a polyamide resin, a polyimide resin, and/or the like.

According to one or more embodiments, the second protective layer INS2 is disposed to cover at least one end of the contact electrode CTE to prevent short circuit of the pixel electrode PXE and the common electrode CE.

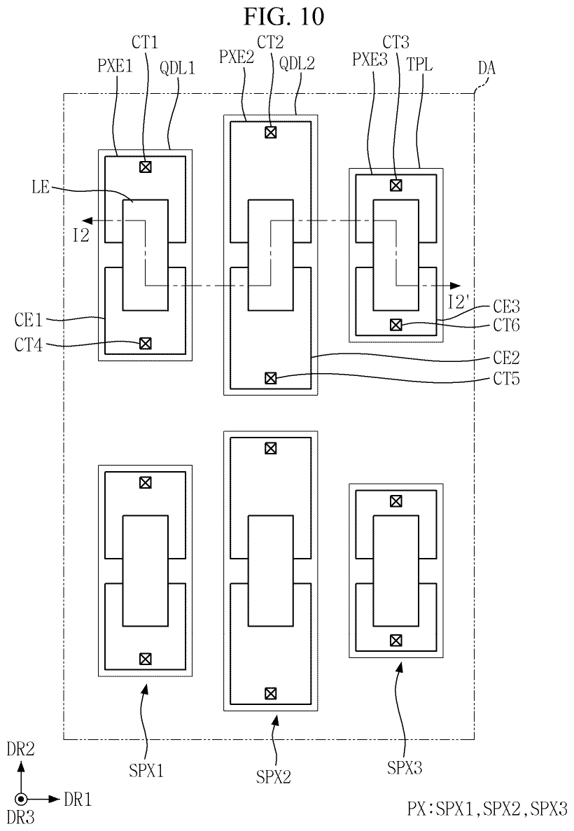

FIG. 10 is a layout diagram illustrating pixels of a display area according to one or more embodiments.

The embodiment of FIG. 10 differs from the embodiment of FIG. 5 in that the first sub-pixel SPX1 further includes a first common electrode CE1, the second sub-pixel SPX2 further includes a second common electrode CE2, the third sub-pixel SPX3 further includes a third common electrode CE3, and the light emitting element LE is a flip-type micro LED. In the embodiment of FIG. 10, descriptions overlapping with the embodiment of FIG. 5 will be omitted.

Referring to FIG. 10, each of the pixel electrodes PXE1, PXE2, and PXE3 and the common electrodes CE1, CE2, and CE3 may have a rectangular planar shape. The area of the first pixel electrode PXE1 may be the same as the area of the first common electrode CE1, the area of the second pixel electrode PXE2 may be the same as the area of the second common electrode CE2, the area of the third pixel electrode PXE3 may be the same as the area of the third common electrode CE3, but the present disclosure is not limited thereto.

In the first sub-pixel SPX1, the first pixel electrode PXE1 and the first common electrode CE1 may be arranged to be spaced (e.g., spaced apart) in the second direction DR2. In the second sub-pixel SPX2, the second pixel electrode PXE2 and the second common electrode CE2 may be arranged to be spaced (e.g., spaced apart) in the second direction DR2. In the third sub-pixel SPX3, the third pixel electrode PXE3 and the third common electrode CE3 may be arranged to be spaced (e.g., spaced apart) in the second direction DR2.

The first common electrode CE1 may be connected to a second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3.

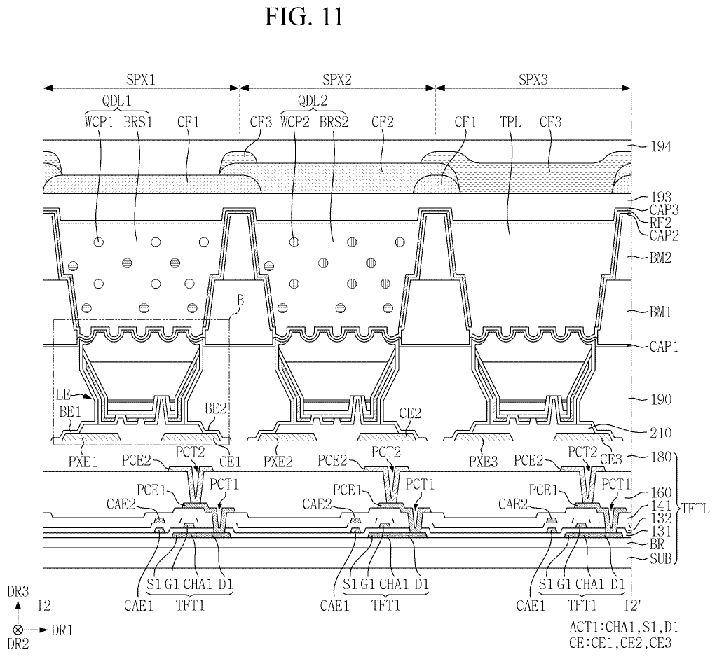

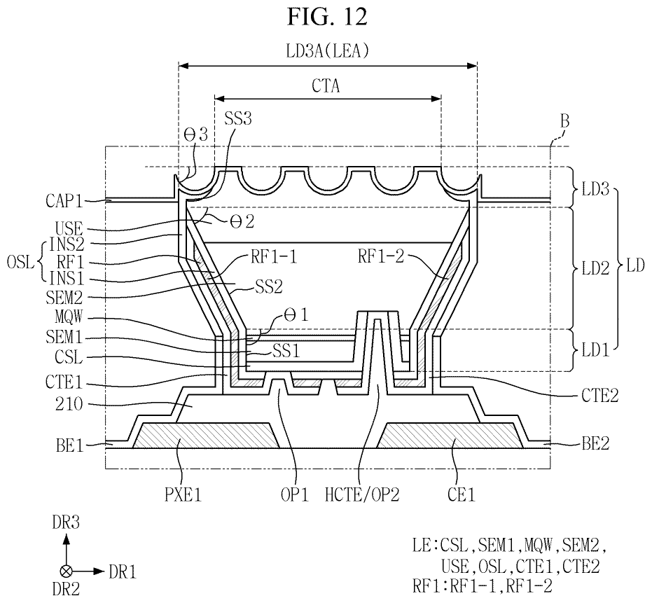

FIG. 11 is a cross-sectional view illustrating an example of cross-section of a display panel corresponding to the line I2-I2′ in FIG. 10. FIG. 12 is a cross-sectional view illustrating an example of an area B in FIG. 11 in detail.

The embodiments of FIGS. 11 and 12 are different from the embodiments of FIGS. 6 and 7 in that the light emitting element LE is a flip-type micro LED. In the embodiments of FIGS. 11 and 12, descriptions overlapping with those of the embodiments of FIGS. 6 and 7 will be omitted.

Referring to FIGS. 11 and 12, the light emitting element LE may be a flip-type micro LED. The flip-type micro LED refers to an LED in which contact electrodes CTE1 and CTE2 are formed on one side (e.g., bottom side) of the light emitting element LE.

A pixel electrode layer including pixel electrodes PXE1, PXE2, and PXE3 and common electrodes CE1, CE2, and CE3 may be disposed on the second organic film 180.

Each of the light emitting elements LE may include a current spreading layer CSL, a first semiconductor layer SEM1, an active layer MQW, a second semiconductor layer SEM2, a third semiconductor layer USE, and an outer shell layer OSL. In one or more embodiments, each of the light emitting elements LE may omit the current spreading layer CSL. In one or more embodiments, each of the light emitting elements LE may further include contact electrodes CTE1 and CTE2. For example, the first contact electrode CTE1 may be electrically connected to the current spreading layer CSL, and the second contact electrode CTE2 may contact and may be electrically connected to the second semiconductor layer SEM2. In one or more embodiments, when the current spreading layer CSL is omitted, the first contact electrode CTE1 may be electrically connected to the first semiconductor layer SEM1.

The light emitting element LE has a groove HCTE on one surface that penetrates the current spreading layer CSL, the first semiconductor layer SEM1, and the active layer MQW, and exposes the second semiconductor layer SEM2. The second contact electrode CTE may be connected to the second semiconductor layer SEM2 through the groove HCTE formed through the current spreading layer CSL, the first semiconductor layer SEM1, the active layer MQW, and the second semiconductor layer SEM2.

The outer shell layer OSL may be disposed on at least one side and a side surface of the element rod LD. The outer shell layer OSL may include a first protective layer INS1, a first reflective layer RF1, and a second protective layer INS2.

The first protective layer INS1 may include a first opening OP1 and a second opening OP2 on one side of the first element rod LD1. The first opening OP1 and the second opening OP2 may be arranged to be spaced (e.g., spaced apart) from each other. The first opening OP1 may be disposed on one side of the first element rod LD1, and in one or more embodiments, the second opening OP2 may be disposed to overlap the bottom of the groove HCTE. For example, the second semiconductor layer SEM2 may be exposed through the second opening OP2 of the first protective layer INS1 overlapping the groove HCTE.

The first reflective layer RF1 may include a 1-1 reflective layer RF1-1 and a 1-2 reflective layer RF1-2. Further, ends of the 1-1 reflective layer RF1-1 and the 1-2 reflective layer RF1-2 may be disposed to be spaced (e.g., spaced apart) from each other. The 1-1 reflective layer RF1-1 and the 1-2 reflective layer RF1-2 are not electrically connected.

In one or more embodiments, the 1-1 reflective layer RF1-1 may be disposed on the current spreading layer CSL exposed through the first opening OP1 of the first protective layer INS1. In one or more embodiments, the 1-1 reflective layer RF1-1 is electrically connected to the current spreading layer CSL.

In one or more embodiments, the 1-2 reflective layer RF1-2 may be disposed on the second semiconductor layer SEM2 exposed through the second opening OP2 of the first protective layer INS1 and extend to the side of the groove HCTE. The 1-2 reflective layer RF1-2 is electrically connected to the second semiconductor layer SEM2 (e.g., via the second contact electrode CTE2).

In one or more embodiments, the first contact electrode CTE1 may be disposed on the pixel electrode PXE of each sub-pixel SPX (e.g., with the organic pattern layer 210 interposed therebetween). For example, in one or more embodiments, the first contact electrode CTE1 may be disposed between the pixel electrode PXE and the light emitting element LE of each sub-pixel SPX.

The first contact electrode CTE1 is disposed on the first reflective layer RF1 to follow the first reflective layer RF1, for example, the 1-1 reflective layer RF1-1. One end of the first contact electrode CTE1 is disposed on one surface of the light emitting element LE and is electrically connected to the current spreading layer CSL through the first opening OP1. In one or more embodiments, the 1-1 reflective layer RF1-1 may be electrically connected to the current spreading layer CSL through the first contact electrode CTE1 on the first opening OP1. One end of the first contact electrode CTE1 extends along one side of the light emitting element LE and may be disposed to cover the 1-1 reflective layer RF1-1.

The first contact electrode CTE1 may electrically connect the first semiconductor layer SEM1 of the light emitting element LE to the pixel electrode PXE of each sub-pixel SPX through a first connection electrode BE1, which will be described later.

In one or more embodiments, the second contact electrode CTE2 may be disposed on the common electrode CE of each sub-pixel SPX (e.g., with the organic pattern layer 210 interposed therebetween). For example, in one or more embodiments, the second contact electrode CTE2 may be disposed between the common electrode CE and the light emitting element LE of each sub-pixel SPX. The second contact electrode CTE2 is disposed on the first reflective layer RF1 to follow the first reflective layer RF1, for example, the 1-2 reflective layer RF1-2. One end of the second contact electrode CTE2 may be disposed on one surface of the light emitting element LE and extend to the side of the groove HCTE. The second contact electrode CTE2 is electrically connected to the second semiconductor layer SEM2 through the second opening OP2. One end of the second contact electrode CTE2 extends along one side of the light emitting element LE and may be disposed to cover the 1-2 reflective layer RF1-2. In one or more embodiments, the 1-2 reflective layer RF1-2 may be electrically connected to the second semiconductor layer SEM2 through the second contact electrode CTE2 on the second opening OP2.

In addition, one end of the first contact electrode CTE1 and the second contact electrode CTE2 may be disposed to be spaced (e.g., spaced apart) from each other. The first contact electrode CTE1 and the second contact electrode CTE2 are not electrically connected.

The second contact electrode CTE2 may connect the second semiconductor layer SEM2 of the light emitting element LE to the common electrode CE of each sub-pixel SPX through a second connection electrode BE2.

The first contact electrode CTE1 and the second contact electrode CTE2 may include a metal, metal oxide, and/or another conductive material with higher conductivity than the first reflective layer RF1. For example, the first contact electrode CTE1 and the second contact electrode CTE2 may include gold (Au), copper (Cu), and/or chromium (Cr).

The second protective layer INS2 may be disposed on at least a portion of the side of the element rod LD. For example, the second protective layer INS2 may be disposed on the side of the second element rod LD2 and the third element rod LD3, and may extend from the side of the third element rod LD3 and may be disposed at least partially on one side of the third element rod LD3. For example, the second protective layer INS2 may be partially disposed along the unevenness of the third element rod LD3. Accordingly, the contact area CTA between the common electrode CE in the third element rod LD3 on a plane may be smaller than the area LD3A of the third element rod LD3. In addition, on a plane (e.g., in a plan view), the area LEA of the third element rod LD3 may be the same as the area LEA of the light emitting element LE, so the contact area CTA may be smaller than the area LEA of the light emitting element LE.

The second protective layer INS2 may cover and protect one end of the first contact electrode CTE1 and one end of the second contact electrode CTE2.

The connection electrode BE may include a first connection electrode BE1 and a second connection electrode BE2.

The first connection electrode BE1 connects the first contact electrode CTE1 to one of the pixel electrodes PXE1, PXE2, and PXE3. Further, the first connection electrode BE1 may be disposed on the top and side surfaces of the organic pattern layer 210. Additionally, the first connection electrode BE1 may be disposed on a portion of the side surface of the light emitting element LE on the first contact electrode CTE1. For example, the first connection electrode BE1 may be disposed on a portion of the first contact electrode CTE1.

The second connection electrode BE2 connects the second contact electrode CTE2 to one of the common electrodes CE1, CE2, and CE3. Further, the second connection electrode BE2 may be disposed on the top and side surfaces of the organic pattern layer 210. Additionally, the second connection electrode BE2 may be disposed on a portion of the side surface of the light emitting element LE on the second contact electrode CTE2. For example, the second connection electrode BE2 may be disposed on a portion of the second contact electrode CTE2.

Each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material (TCO), such as indium tin oxide (ITO) and/or indium zinc oxide (IZO), that is capable of transmitting light.

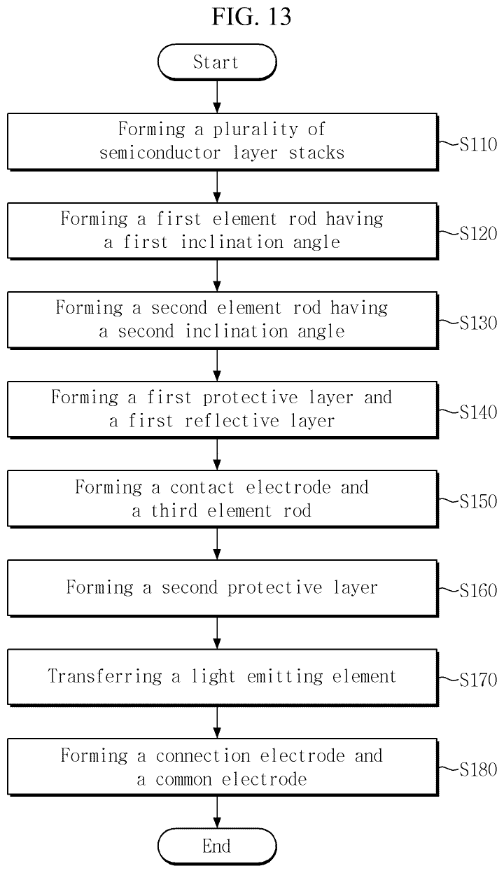

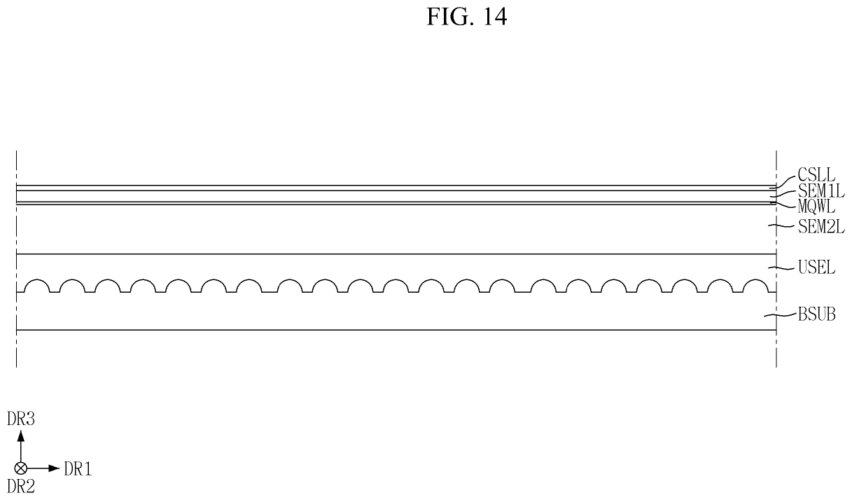

FIG. 13 is a flowchart illustrating a manufacturing method of a display device according to one or more embodiments. FIGS. 14-29 are cross-sectional views to illustrate a manufacturing method of a display device according to one or more embodiments.

FIGS. 14-29 illustrate the structure according to the formation order of each layer of the display device as a cross-sectional view. FIGS. 14-29 mainly illustrate the formation of the light emitting element and the light emitting element layer (e.g., see FIG. 6), which may generally correspond to the cross-sectional view in FIG. 7, respectively. In the following, a method of manufacturing the display device shown in FIGS. 14-29 will be described in conjunction with FIG. 13.

Referring to FIG. 14, a plurality of semiconductor material layers USEL, SEM2L, MQWL, and SEM1L and a current spreading material layer CSLL are stacked and patterned on a growth substrate BSUB to form a plurality of semiconductor layer stacks. (S110 in FIG. 13)

First, the growth substrate BSUB is prepared. The growth substrate BSUB may be a sapphire substrate Al₂O₃ and/or a silicon wafer including silicon. However, it is not limited thereto, and in one or more embodiments, a case where the growth substrate BSUB is a sapphire substrate will be described as an example.

A plurality of semiconductor material layers USEL, SEM2L, MQWL, SEM1L are formed on the growth substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl and/or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

Specifically, a third semiconductor material layer USEL is formed on the base substrate BSUB. While the drawings illustrate the third semiconductor material layer USEL being further stacked, it is not limited to this, and a plurality of layers may be formed. The third semiconductor material layer USEL may be disposed on the concave-convex structure of the growth substrate BSUB. Accordingly, unevenness is also formed on one surface of the third semiconductor layer USE in contact with the uneven structure of the growth substrate BSUB. The uneven structure of the third semiconductor layer USE corresponds to the uneven structure of the growth substrate BSUB. For example, upwardly convex unevenness is formed on one surface of the third semiconductor layer USE that is in contact with the upwardly convex unevenness of the growth substrate BSUB. The unevenness may be one of a hemisphere shape, a cone shape, a truncated cone shape, a pyramid shape, a truncated pyramid shape, and/or a cylinder shape but are not limited thereto.

The third semiconductor material layer USEL may be disposed to reduce a lattice constant difference between a second semiconductor material layer SEM2L and the growth substrate BSUB. For example, the third semiconductor material layer USEL may include an undoped semiconductor, which may be an n-type or p-type undoped material. In one or more embodiments, the third semiconductor material layer USEL may be undoped InAlGaN, GaN, AlGaN, InGaN, AlN, and/or InN but is not limited thereto.

The second semiconductor material layer SEM2L, the active material layer MQWL, and the first semiconductor material layer SEM1L are sequentially formed on the third semiconductor material layer USEL using the above-described method. In another modified example, a superlattice material layer may be formed between the second semiconductor material layer SEM2L and the active material layer MQWL. Furthermore, an electron blocking material layer may be formed between the active material layer MQWL and the first semiconductor material layer SEM1L. A current spreading material layer CSLL may be further formed on the first semiconductor material layer SEM1L. The current spreading material layer CSLL may be made of a transparent metal material (TCO) such as indium tin oxide (ITO) and/or indium zinc oxide (IZO) that may transmit light.

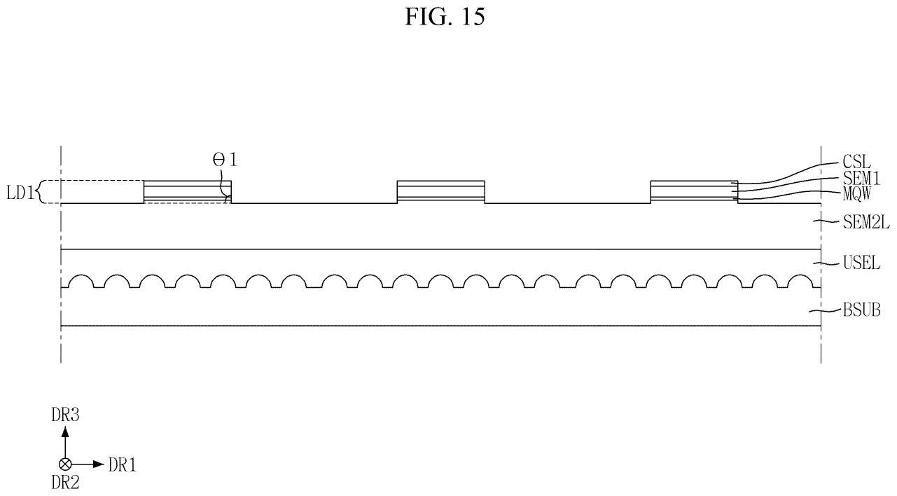

Referring to FIG. 15, an active material layer MQWL and a first semiconductor material layer SEM1L may be etched using a first mask to form a first element rod LD1 having a first tilt angle θ1. (S120 in FIG. 13)

For example, at least the current spreading material layer CSLL, the first semiconductor material layer SEM1L, and the active material layer MQWL are dry etched using the first mask. At this time, a portion of the second semiconductor material layer SEM2L may be further etched.

During dry etching, as the etching depth increases, the process time increases and the plasma exposure time of the semiconductor material layer increases, which may increase damage to the active layer. Therefore, in one or more embodiments, the first semiconductor material layer SEM1L, the active material layer MQWL, the second semiconductor material layer SEM2L, and the third semiconductor material layer USEL are not etched at once, but only a portion of the current spreading material layer CSLL, the first semiconductor material layer SEM1L, the active material layer MQWL, and the second semiconductor material layer SEM2L corresponding to about 1/10 of the total semiconductor material layer is etched. Therefore, damage to the active layer may be reduced or minimized. Afterwards, additional wet etching may be performed.

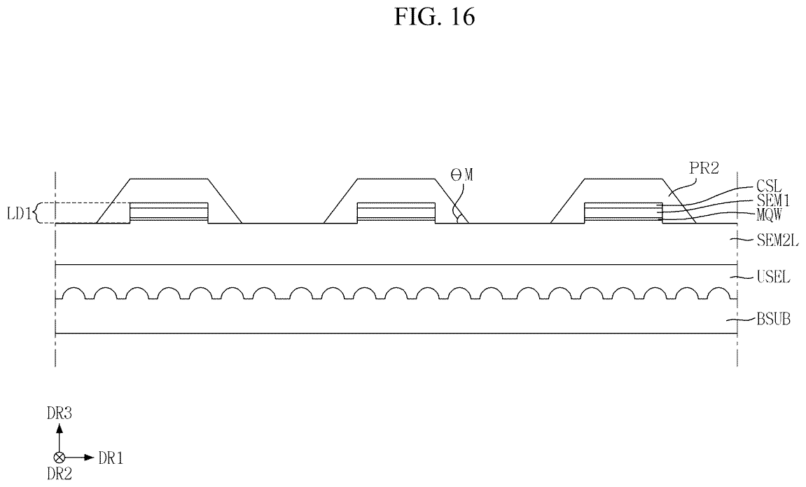

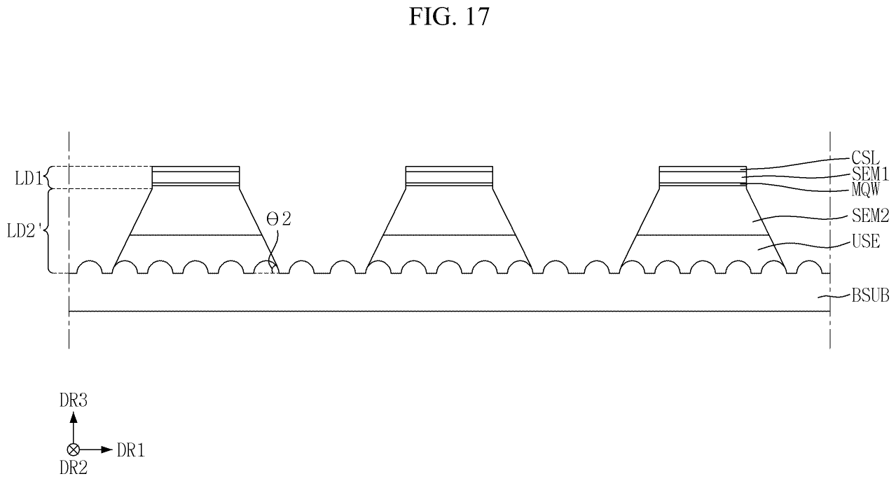

Referring to FIGS. 16 and 17, a second semiconductor material layer SEM2L and a third semiconductor material layer USEL may be etched using a second mask to form a second element rod LD2′ having a second inclination angle θ2. (S130 in FIG. 13).

For example, referring to FIG. 16, a dielectric material such as ZAZ (ZrO₂/Al₂O₃/ZrO₂) is applied on the first element rod LD1 for wrapping.

Then, the second element rod LD2 is formed through a photo process. The photo process in which a photoresist (PR) is applied to a substrate and light is passed through a mask with a desired pattern to form a desired structure. For example, the photoresist PR2 may be formed to wrap around the first element rod LD1. The photoresist PR2 may have the shape of a square pillar whose width becomes narrower toward the top. An inclination angle θM of the photoresist PR2 may be greater than 60 degrees and less than or equal to 80 degrees.

The second semiconductor material layer SEM2L and the third semiconductor material layer USEL are patterned using the second mask. For example, the second semiconductor material layer SEM2L and the third semiconductor material layer USEL may be formed through a dry etching process to form the second semiconductor layer SEM2 and the third semiconductor layer USE. Depending on the shape of the photoresist PR2, the width may increase from the second semiconductor layer SEM2 toward the third semiconductor layer USE. The inclination angle of the second element rod LD2 may be formed to be greater than 60 degrees and less than or equal to 80 degrees corresponding to the inclination angle θM of the photoresist PR. Through this process, each light emitting element may be separated from each other.

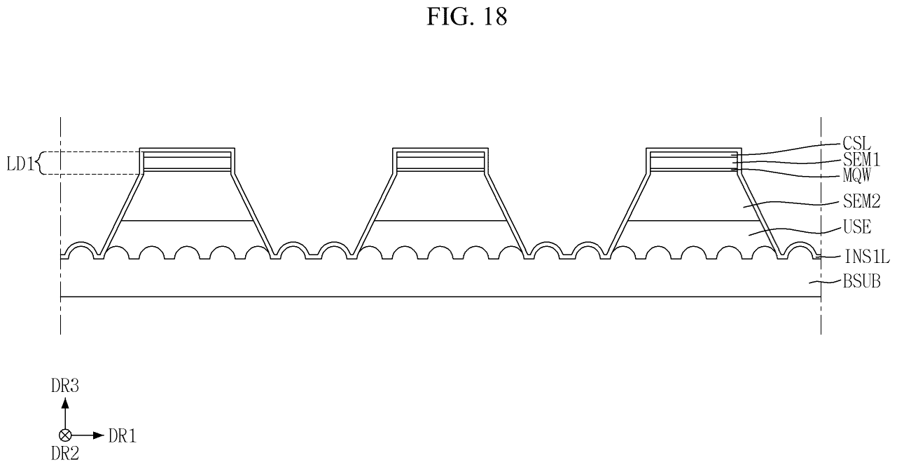

Referring to FIGS. 18-20, a first protective layer INS1 covering the third semiconductor layer USE, the second semiconductor layer SEM2, the active layer MQW, the first semiconductor layer SEM1, and the current spreading layer CSL and a first reflective layer RF1 covering the first semiconductor layer SEM1, the second semiconductor layer SEM2, and the active layer MQW may be formed. (S140 in FIG. 13)

For example, referring to FIG. 18, a first protective material layer INS1L is formed on the growth substrate BSUB to cover the first element rod LD1, the second semiconductor layer SEM2, and the third semiconductor layer USE. The first protective material layer INS1L may be formed as an inorganic film, such as a silicon nitride layer, a silicon oxynitride layer, a silicon oxide layer, a titanium oxide layer, and/or an aluminum oxide layer but is not limited thereto.

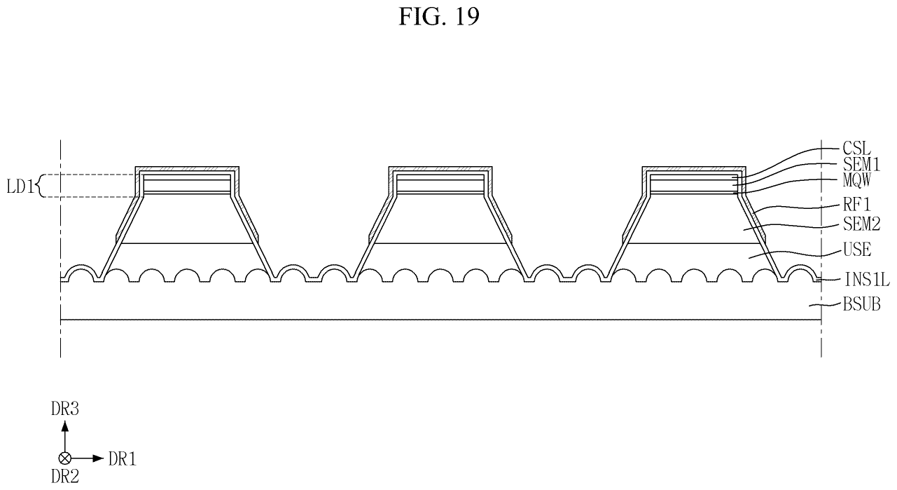

Referring to FIG. 19, a first reflective material layer is formed on the first protective material layer INS1L to cover the first element rod LD1, the second semiconductor layer SEM2, and the third semiconductor layer USE. The first reflective material layer may be deposited through a process such as sputtering but is not limited thereto.

Next, the first reflective layer RF1 may be formed by etching a portion of the first reflective material layer through a photo process using a third mask. For example, the first reflective material layer disposed on the third semiconductor layer USE may be removed. The first reflective material layer may be etched using a wet etching process but is not limited thereto.

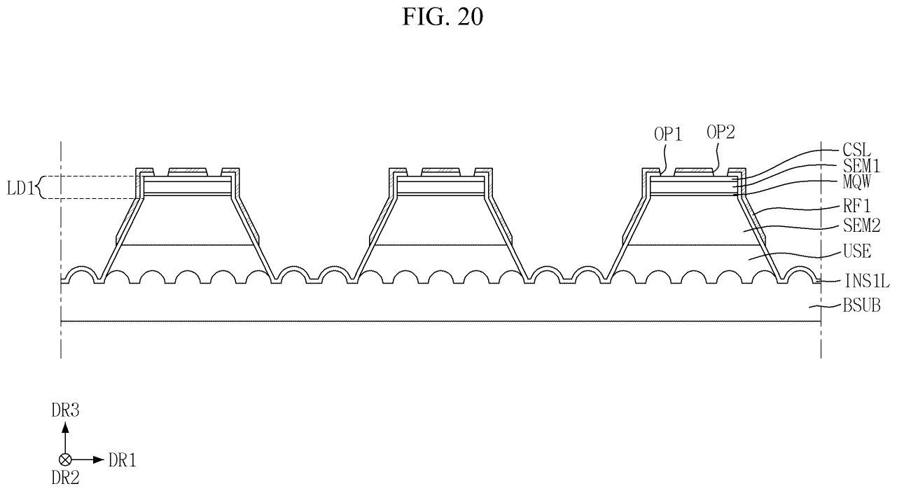

Referring to FIG. 20, a portion of the first reflective layer RF1 is etched on the top surface of the first element rod LD1 using a fourth mask, and one or more openings OP1 and OP2 may be formed overlapping the first protective material layer INS1L with the first reflective layer RF1 as a mask. The first opening OP1 and the second opening OP2 may be formed to be spaced (e.g., spaced apart) from each other. The openings OP1 and OP2 may be formed through a dry etching process but are not limited thereto.

In this process, a portion of the top surface of the current spreading layer CSL may be exposed.

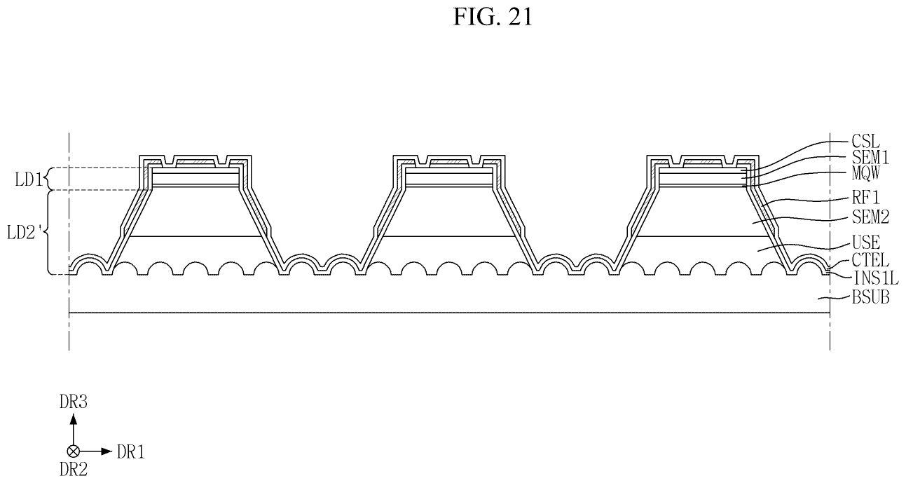

Referring to FIGS. 21-23, a contact electrode CTE and a third element rod LD3 are formed (S150 in FIG. 13).

For example, referring to FIG. 21, a conductive material layer CTEL is formed on the entire surface of the plurality of semiconductor layer stacks and the growth substrate BSUB. The conductive material layer CTEL may be deposited through a process such as sputtering but is not limited to this.

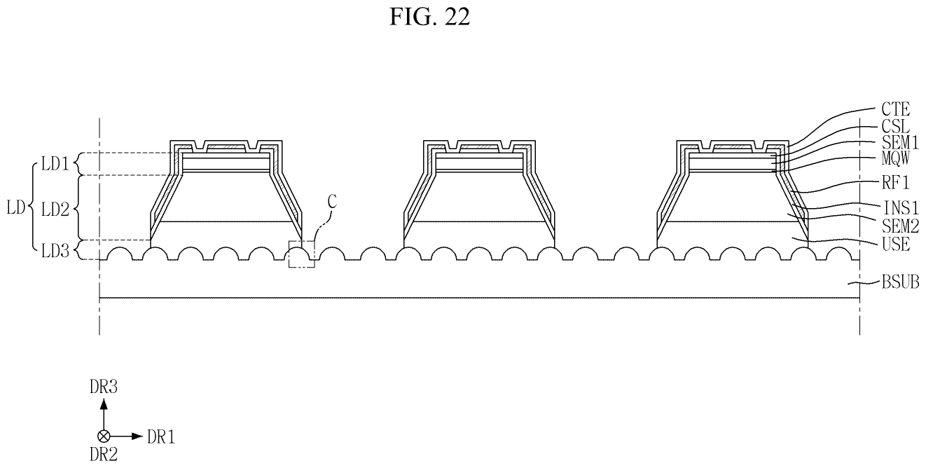

Referring to FIG. 22, a contact electrode CTE is formed by etching a portion of the conductive material layer CTEL using a fifth mask. For example, a photoresist is formed to cover all the conductive material layer CTEL to be the contact electrode CTE, and the contact electrode CTE is formed by etching the conductive material layer CTEL not covered by the photoresist using the fifth mask. One end of the contact electrode CTE may be formed to have a minimum length that may fully cover the first reflective layer RF1. One end of the contact electrode CTE is formed to be spaced (e.g., spaced apart) from the growth substrate BSUB. The photo resist may be removed by an ashing process but is not limited to this.

Next, the third element rod LD3 is formed using the contact electrode CTE as a mask. The portion where the contact electrode CTE is not disposed becomes the third element rod LD3, and the portion of the second element rod (LD2′ in FIG. 21) surrounded by the contact electrode CTE becomes the second element rod LD2. The sides of the contact electrode CTE and the third element rod LD3 may be aligned and matched with each other.

In one or more embodiments, a separate mask may be used instead of using the contact electrode CTE as a mask. When a separate mask is used, as described in FIG. 9, one end of the contact electrode and the side surface of the third element rod LD3 may have a step difference.

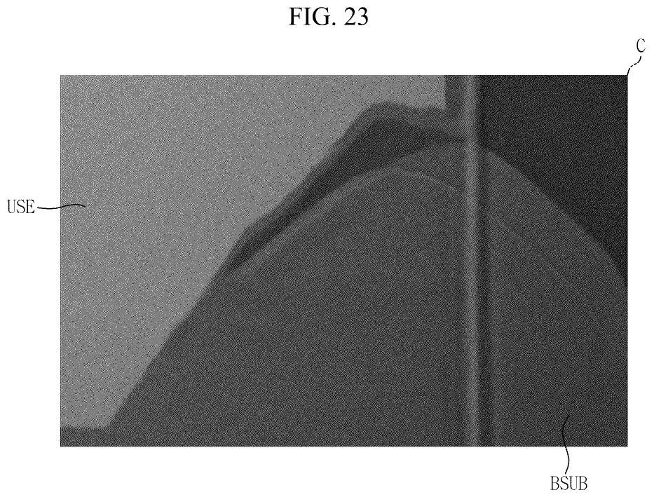

FIG. 23 is an enlarged view of an area C of FIG. 22. As shown in FIG. 23, in the wet etching process of forming the third element rod LD3, a partial gap between the growth substrate BSUB and the third semiconductor layer USE may be formed at the edge of the third semiconductor layer USE. The degree of gap widening may be adjusted by wet etching time and etching material.

In one embodiment, the contact area between the third semiconductor layer USE and the growth substrate BSUB is reduced by the gap formed between the growth substrate BSUB and the third semiconductor layer USE, which may require less energy in a subsequent laser lift-off (LLO) process for separation of the growth substrate BSUB.

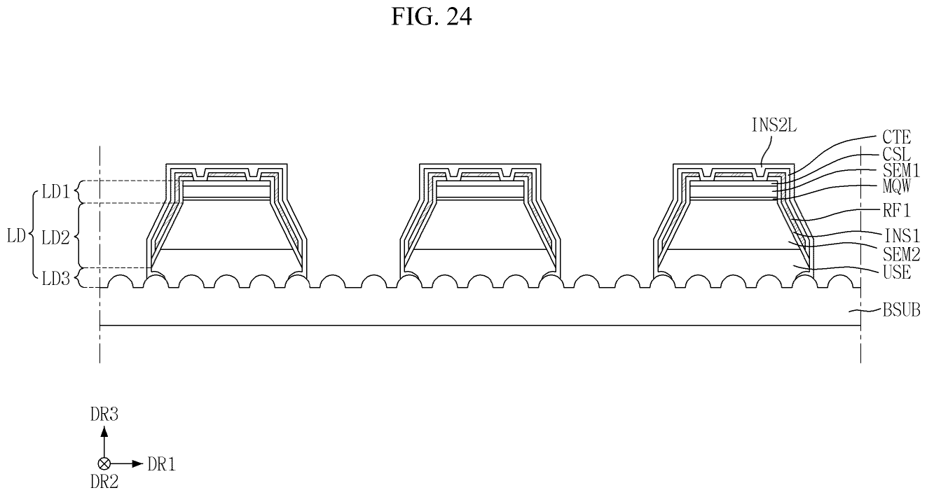

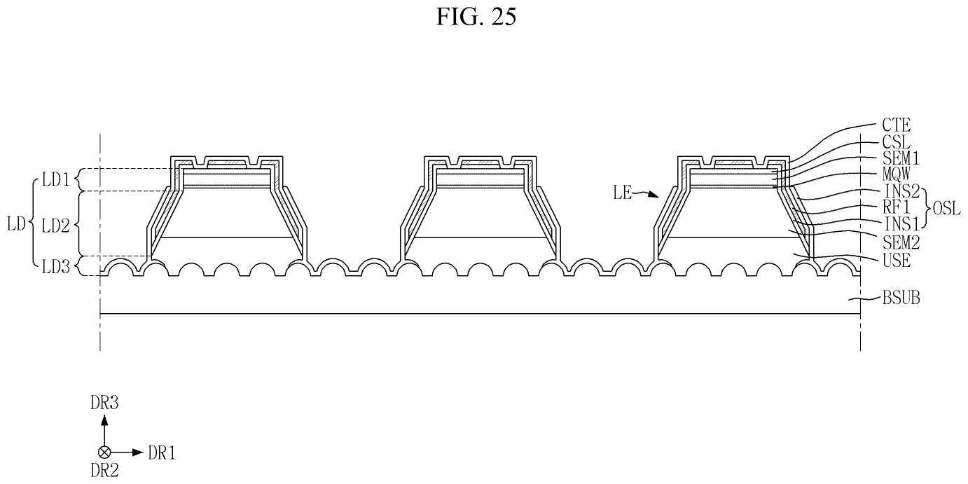

Referring to FIGS. 24 and 25, a second protective layer INS2 is formed (S160 in FIG. 13).

Referring to FIG. 24, the second protective material layer INS2L is applied to the entire growth substrate BSUB. A sputtering method may be used for application but is not limited thereto. When forming the second protective material layer INS2L, the gap between the growth substrate BSUB and the third semiconductor layer USE may be filled with the second protective material layer INS2L.

Referring to FIG. 25, a portion of the second protective material layer INS2L is selectively etched to form the second protective layer INS2.

For example, the second protective material layer INS2L disposed on the top and side surfaces of the first element rod LD1 may be etched using the sixth mask to form the second protective layer INS2 in which the side surface of the second element rod LD2, the side surface of the third element rod LD3, and at least a portion between the third element rod LD3 and the growth substrate BSUB are disposed.

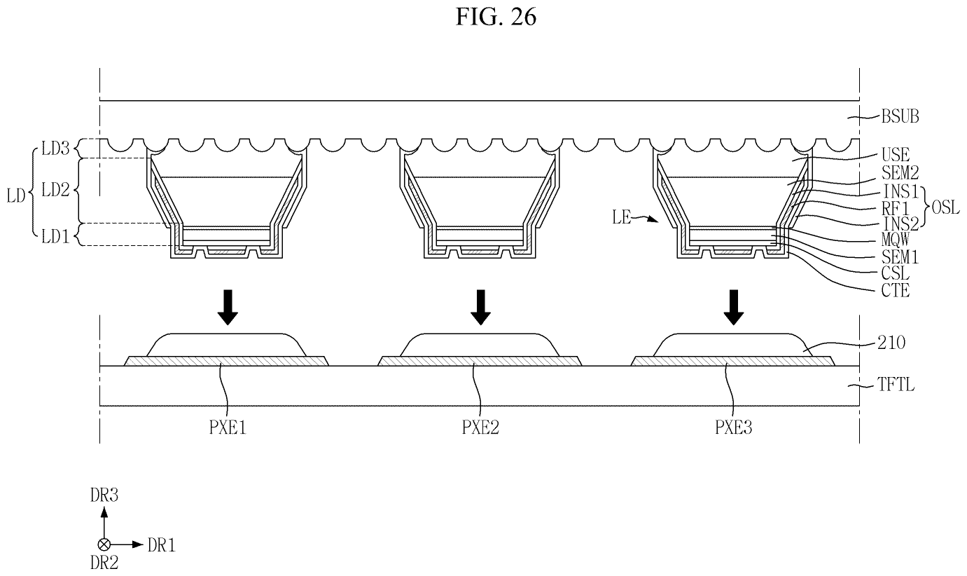

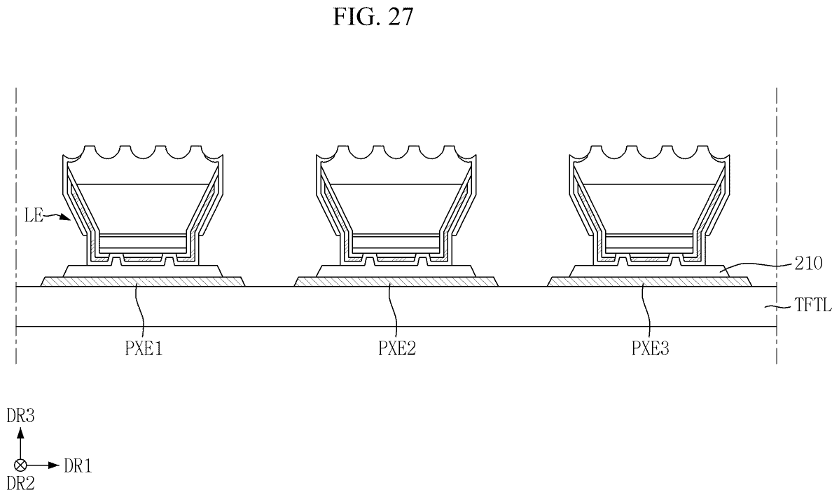

Referring to FIGS. 26 and 27, the light emitting element LE is transferred onto the pixel electrode PXE of the circuit board. (S170 in FIG. 13)

The light emitting element LE of the growth substrate BSUB manufactured in FIG. 26 is transferred to the target substrate. In one or more embodiments, the target substrate is described as a circuit board for convenience of explanation, but it is not limited thereto. For example, the target substrate may be a relay substrate.

The light emitting element LE of the growth substrate BSUB is aligned at a desired position on the target substrate. For example, an organic pattern layer 210 is formed on the pixel electrode PXE, and the light emitting element LE is disposed on the organic pattern layer 210.

The organic pattern layer 210 may be a photosensitive organic layer such as photoresist. Alternatively, the organic pattern layer 210 may be formed from an acrylic resin, an epoxy resin, a phenolic resin, a polyamide resin, a polyimide resin, and/or the like. The thickness of the organic pattern layer 210 may be thicker than the thickness of the pixel electrode layer.

A portion of the light emitting element LE disposed on the organic pattern layer 210 may be temporarily fixed by being embedded in the organic pattern layer 210. For example, a portion of the contact electrode CTE of the plurality of light emitting elements LE may be embedded and fixed in the organic pattern layer 210.

As such, when the organic pattern layer 210 is a photosensitive organic layer such as a photoresist, at least a portion of each of the plurality of light emitting elements LE may be inserted into the organic pattern layer 210 after soft baking the organic pattern layer 210 at the first temperature. Then, the organic pattern layer 210 may be completely cured at a second temperature higher than the first temperature. The first temperature may be approximately 100 degrees Celsius, and the second temperature may be approximately 230 degrees Celsius, but the present disclosure is not limited thereto. In the first curing, the first temperature is low enough to completely cure the organic pattern layer 210, so the organic pattern layer 210 may have fluidity. On the other hand, the second curing is performed at the second temperature for approximately 30 minutes and the organic pattern layer 210 may be completely cured. The fully cured organic pattern layer 210 does not have fluidity. The light emitting element LE embedded when it has fluidity after primary curing may be completely fixed to the organic pattern layer 210 after second curing.

Afterwards, the light emitting elements LE may be separated from the growth substrate BSUB. The growth substrate BSUB is separated from each third semiconductor layer USE of the plurality of light emitting elements LE.

The process of separating the growth substrate BSUB may be done using a laser lift-off (LLO) process. The laser lift-off process uses a laser, and a KrF excimer laser (248 nm wavelength) may be used as the source. The energy density of the excimer laser is irradiated in the range of about 550 mJ/cm² to 950 mJ/cm², and the incident area may be in the range of 50×50 μm 2 to 1×1 cm but is not limited thereto. By irradiating the laser to the growth substrate BSUB, the growth substrate BSUB may be separated from the light emitting element LE.

In this way, after the lift-off process, a cleaning process may be performed to remove contaminants from the light emitting element. For example, Cl₂ may be used for the cleaning process, where HCl and the like may be formed. In this way, even if HCl is formed, the first reflective layer RF1 is not exposed in the light emitting element LE according to one or more embodiments, so damage to the first reflective layer RF1 may be reduced or minimized. For example, if one end of the first reflective layer RF1 made of aluminum (Al), silver (Ag), etc. is exposed, not only the exposed reflective layer but also a large portion of the reflective layer may be damaged by penetrating through the exposed reflective layer.

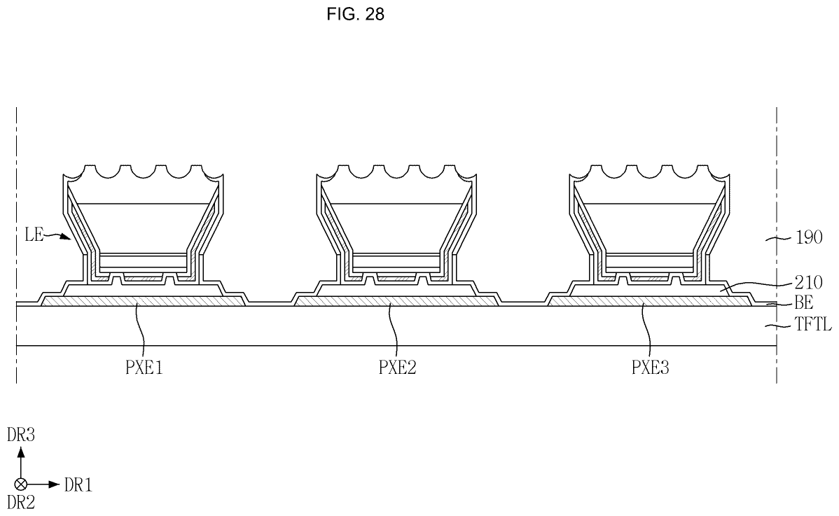

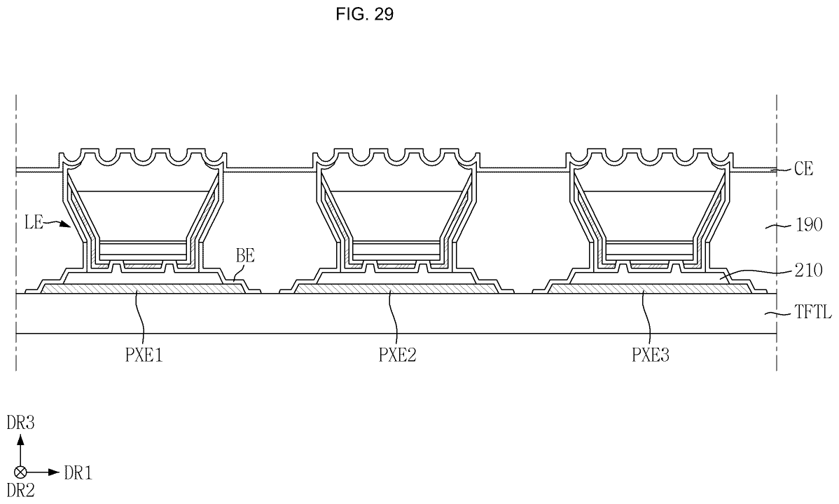

Thereafter, referring to FIGS. 28 and 29, a connection electrode BE and a common electrode CE are formed (S180 in FIG. 13).

For example, referring to FIG. 28, after forming a conductive material layer on a circuit board, a portion of the conductive material layer may be removed through a photo process to form the connection electrode BE connecting the contact electrode CTE of the light emitting element LE and the pixel electrodes PXE1, PXE2, and PXE3. The connection electrode BE is formed on the contact electrode CTE, and the second protective layer INS2 and the connection electrode BE may not overlap each other on the side of the light emitting element LE.

The connection electrode BE may serve as a bonding metal for bonding the pixel electrodes PXE and the light emitting elements LE.

Referring to FIG. 29, a third organic layer 190 is formed on the thin film transistor layer TFTL on the substrate SUB on which the light emitting element LE is not disposed. The third organic layer 190 may fill the space between the light emitting elements LE and may be formed to cover the side surfaces of the light emitting elements LE. The third organic layer 190 may be formed lower than the height of the light emitting element LE. Accordingly, the top surface of the light emitting element LE may be exposed.

The common electrode CE covers the light emitting element LE and the third organic layer 190 and may be formed in direct contact with them. The common electrode CE may be continuously formed throughout the display area. The common electrode CE may be formed along the irregularities of the top surface of the third semiconductor USE of the light emitting element LE.

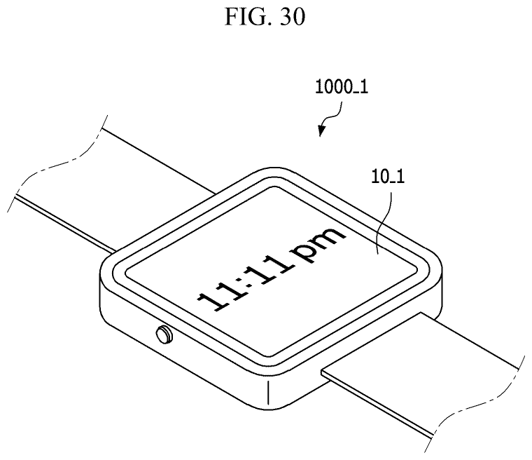

FIG. 30 is an example view of a smart watch including a display device according to one or more embodiments.

Referring to FIG. 30, a display device 10_1 according to one or more embodiments may be applied to a smart watch 1000_1 which is one of smart devices.

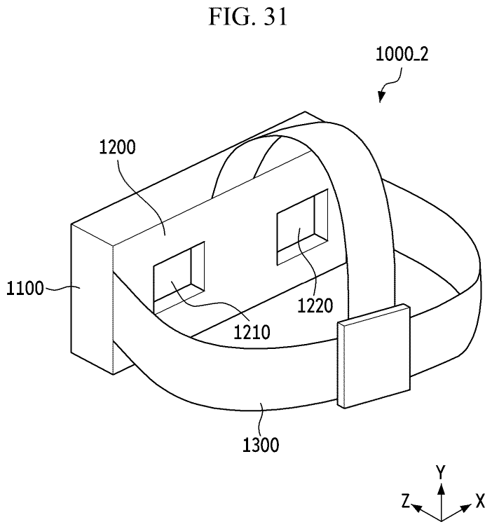

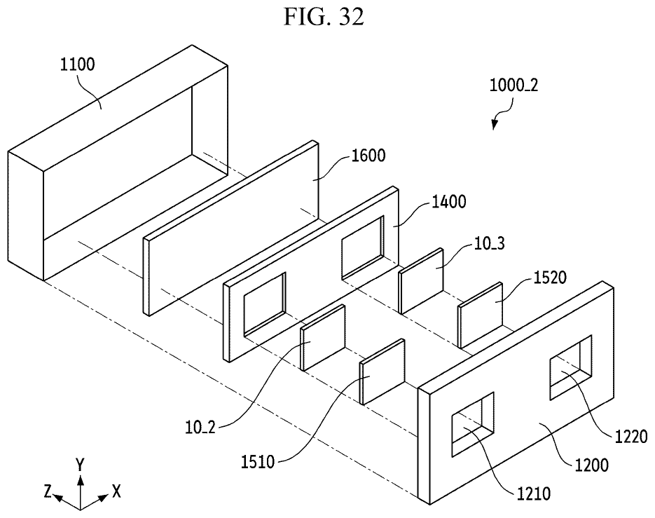

FIGS. 31 and 32 are example views of a virtual reality (VR) device including a display device according to one or more embodiments.

Referring to FIGS. 31 and 32, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

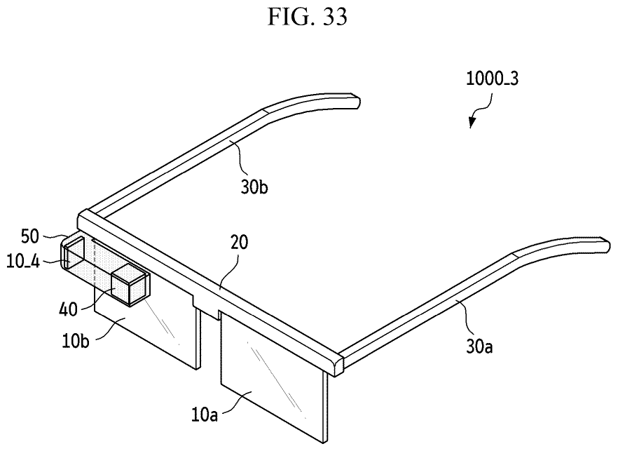

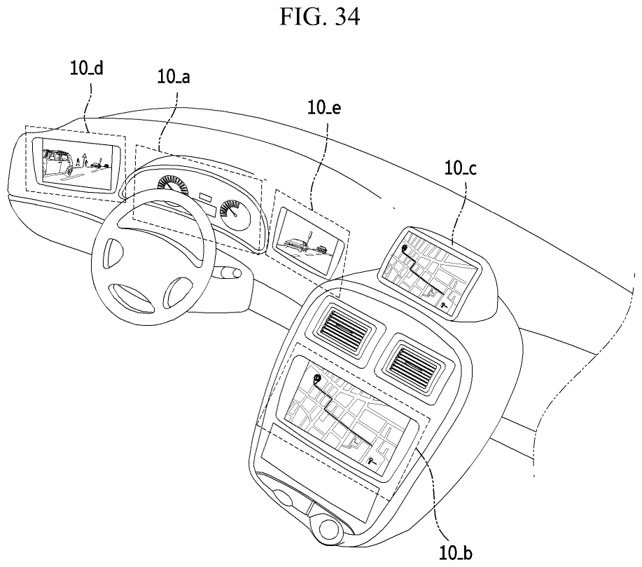

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 33 and 34, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 33 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 33 is an example view of a VR device including a display device according to one or more embodiments. FIG. 33 illustrates a VR device 1000_3 to which a display device 10_4 according to one or more embodiments has been applied.

Referring to FIG. 33, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

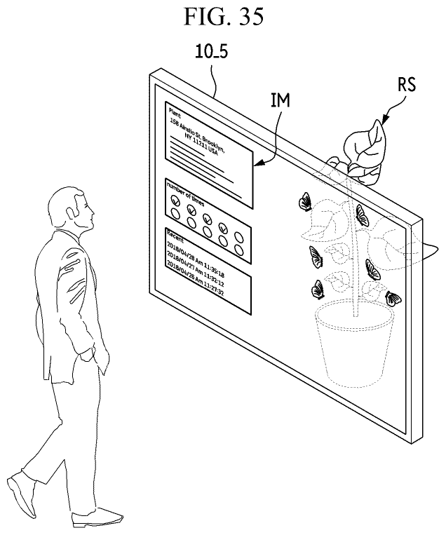

In FIG. 33, a case where the VR device 1000_3 is a glasses-type display device including the eyeglass frame legs 30a and 30b is illustrated as an example. That is, the VR device 1000_3 according to the embodiment is not limited to the one illustrated in FIG. 35 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 33, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

FIG. 34 is an example view illustrating a vehicle instrument cluster and center fascia including display devices according to one or more embodiments. FIG. 34 illustrates a vehicle to which display devices 10_a through 10_e according to one or more embodiments have been applied.

Referring to FIG. 34, the display devices 10_a through 10_c according to the embodiment may be applied to an instrument cluster of the vehicle, a center fascia of the vehicle, and/or a center information display (CID) disposed on a dashboard of the vehicle. In addition, the display devices 10_d and 10_e according to the embodiment may be applied to room mirror displays that replace side mirrors of the vehicle.

FIG. 35 is an example view of a transparent display device including a display device according to one or more embodiments.

Referring to FIG. 35, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles and scope of the present disclosure. Therefore, the disclosed embodiments of the present disclosure are used in a generic and descriptive sense and not for purposes of limitation

What is claimed is:

1. A display device comprising:
a substrate on which a pixel electrode is located;
a light emitting element on the pixel electrode and comprising an element rod and a contact electrode on one surface and a side surface of the element rod;
a connection electrode electrically connecting the contact electrode and the pixel electrode; and
a common electrode on the light emitting element,
wherein the element rod comprises:
a first element rod comprising a first semiconductor layer and an active layer and having a side surface having a first inclination angle;
a second element rod on the first element rod and having a side surface having a second inclination angle; and
a third element rod on the second element rod and having a side surface having a third inclination angle,
wherein the light emitting element further comprises:
a first protective layer on one side and a side of the first element rod and on a side of the second element rod,
a reflective layer on the first protective layer and on one side and a side of the first element rod and on a side of the second element rod; and
a second protective layer on the side surface of the second element rod, the side surface of the third element rod, and an edge of a top surface of the third element rod.

2. The display device of claim 1, wherein the contact electrode is on one surface of the first element rod on the reflective layer and extends to the side surface of the first element rod and the side surface of the second element rod.

3. The display device of claim 1, wherein the contact electrode is located between the reflective layer and the second protective layer on the side of the second element rod,
wherein one end of the reflective layer is surrounded by the first protective layer and the contact electrode on the side of the second element rod.

4. The display device of claim 1, wherein the first protective layer, the reflective layer, and the contact electrode are not on the side of the third element rod.

5. The display device of claim 1, wherein a third semiconductor layer of the element rod has a concavo-convex structure.

6. The display device of claim 5, wherein the second protective layer extends from the side of the third element rod and is located at an edge of the concavo-convex structure of the third semiconductor layer.

7. The display device of claim 1, wherein the second protective layer becomes thinner from a top surface of a third semiconductor layer of the element rod inwardly.

8. The display device of claim 1, further comprising an organic pattern layer on the pixel electrode and on a lower surface of the light emitting element,
wherein the connection electrode is on one side of the pixel electrode, a side of the organic pattern layer, and a side of a first contact electrode of the contact electrode of the light emitting element.

9. The display device of claim 1, wherein the first protective layer has one or more openings defined on one surface of the first element rod,
wherein the contact electrode is electrically connected to the element rod exposed by the opening.

10. The display device of claim 1, wherein the contact electrode has higher conductivity and lower reflectivity than the reflective layer.

11. The display device of claim 1, wherein the second inclination angle is smaller than the first inclination angle and the third inclination angle.

12. The display device of claim 11, wherein the second inclination angle is between 60 degrees and 80 degrees.

13. The display device of claim 1, wherein a width of the second element rod becomes wider toward the third element rod, and a width of the third element rod is wider than a width of the first element rod.

14. A light emitting element comprising:
an element rod in which a first semiconductor layer, an active layer, a second semiconductor layer, and a third semiconductor layer are stacked in sequence, and are compartmentalized into a first element rod, a second element rod, and a third element rod according to an inclination angle;
a first protective layer on one side and a side of the first element rod and on a side of the second element rod,
a reflective layer on the first protective layer and on the one side and the side of the first element rod and on the side of the second element rod;
a contact electrode on the one side of the first element rod on the reflective layer and extending to the side of the first element rod and the side of the second element rod; and
a second protective layer on the side of the second element rod, a side of the third element rod, and an edge of a top surface of the third element rod.

15. The light emitting element of claim 14, wherein the third semiconductor layer has a concavo-convex structure,
wherein the second protective layer is at an edge of the concavo-convex structure of the third semiconductor layer.

16. The light emitting element of claim 14, wherein the second protective layer becomes thinner from a top surface of the third semiconductor layer inwardly.

17. The light emitting element of claim 14, wherein a second inclination angle of the second element rod is smaller than a first inclination angle of the first element rod and a third inclination angle of the third element rod,
wherein the second inclination angle is between 60 degrees and 80 degrees.

18. A manufacturing method of a display device comprising:
forming a third semiconductor material layer, a second semiconductor material layer, an active material layer, and a first semiconductor material layer on a growth substrate;
forming a first element rod having a first inclination angle by etching the active material layer and the first semiconductor material layer using a first mask;
forming a second element rod having a second inclination angle by etching the second semiconductor material layer and the third semiconductor material layer using a second mask;
forming a first protective layer, a reflective layer, and a contact electrode covering the third semiconductor material layer, the second semiconductor material layer, the active material layer, and the first semiconductor material layer;
forming a third element rod having a third inclination angle by etching a portion of the second element rod using a third mask; and
forming a second protective layer on a side surface of the second element rod and a side surface of the third element rod,
wherein the second protective layer extends from the side surface of the third element rod and is between an edge gap between the third element rod and the second protective layer.

19. The method of claim 18, further comprising:
transferring a light emitting element comprising the first element rod, the second element rod, and the third element rod to a circuit board having a pixel electrode; and
forming a connection electrode connecting the contact electrode and the pixel electrode.

20. The method of claim 19, the transferring the light emitting element to the circuit board having the pixel electrode comprises:
forming an organic pattern layer as a pseudo adhesive layer on the pixel electrode; and
arranging a plurality of light emitting elements on the organic pattern layer and fixing the light emitting elements by curing the organic pattern layer.
